(19) United States
(12) Patent Application Publication
(10) Pub. No.: US 2013/0026881 A1
(43) Pub. Date: Jan. 31, 2013

(54) ACOUSTIC WAVE ELEMENT

(71) Applicants: Shoji Okamoto, Osaka (JP); Rei Goto, Osaka (JP); Hidekazu Nakanishi, Osaka (JP); Hiroyuki Nakamura, Osaka (JP)

(72) Inventors: Shoji Okamoto, Osaka (JP); Rei Goto, Osaka (JP); Hidekazu Nakanishi, Osaka (JP); Hiroyuki Nakamura, Osaka (JP)

(21) Appl. No.: 13/639,119

(22) PCT Filed: May 31, 2011
(86) PCT No.: PCT/JP2011/003025

§ 371 Date: Oct. 3, 2012

(30) Foreign Application Priority Data
Jun. 17, 2010 (JP) 2010-137956
Nov. 11, 2010 (JP) 2010-252543
Nov. 11, 2010 (JP) 2010-252544

(51) Int. Cl. H01L 41/047

(52) U.S. Cl. 310/313 C

(57) ABSTRACT

An IDT electrode includes a first electrode layer mainly made of Mo disposed above the piezoelectric body and a second electrode layer mainly made of Al disposed above the first electrode layer. The IDT electrode has a total thickness not more than 0.15λ. The first electrode layer has a thickness not less than 0.05λ. The second electrode layer has a thickness not less than 0.025λ.

### TECHNICAL FIELD

The present invention relates to an acoustic wave device.

### BACKGROUND ART

FIG. 39 is a schematic sectional view of a conventional acoustic wave device. A conventional method of improving temperature characteristics of a filter including acoustic wave device 1 is to provide silicon oxide film 4 on piezoelectric body 2 to cover IDT electrodes 7.

IDT electrodes 7 are made of molybdenum (Mo) to form electrode patterns by a dry etching and also to improve power resistance characteristics of acoustic wave device 1.

IDT electrodes made of Mo can have a smaller thickness 3 than IDT electrodes made of aluminum (Al) since Mo has a higher specific gravity than Al. This can reduce unevenness of the thickness of silicon oxide film 4.

A conventional technique related to this application is shown in Patent Literature 1.

The conventional acoustic wave device has a problem that acoustic wave device 1 has a large insertion loss since Mo is not so conductive.

### CITATION LIST

### Patent Literature

Patent Literature 1: Japanese Patent Laid-Open Publication No. 2009-290914

### SUMMARY OF THE INVENTION

An object of the present invention is to reduce an insertion loss of an acoustic wave device in the case that the acoustic wave device includes an IDT electrode made of Mo (molybdenum), W (tungsten), or Pt (platinum) which can be patterned by dry etching.

An acoustic wave device according to the present invention includes a piezoelectric body an IDT electrode disposed above the piezoelectric body, an IDT electrode exciting a main acoustic wave having a wavelength λ, a silicon oxide (SiO₂) film disposed above the piezoelectric body to cover the IDT electrode, and a dielectric film disposed above the silicon oxide film. The silicon oxide film has a thickness which is not less than 0.20λ and is less than 1λ. The dielectric film has a thickness ranging from 1λ to 5λ and is made of a medium which allows a transverse wave to propagate through the dielectric film faster than a transverse wave propagating through the silicon oxide film. The IDT electrode includes: a first electrode layer mainly made of Mo disposed above the piezoelectric body and a second electrode layer mainly made of Al disposed above the first electrode layer. The IDT electrode has a total thickness not more than 0.15λ. The first electrode layer has a thickness not less than 0.05λ. The second electrode layer has a thickness not less than 0.025λ.

In this structure, in the acoustic wave device, the total thickness of the IDT electrode not more than 0.15λ reduces the unevenness in thickness of the silicon oxide film. Furthermore, the thickness of the first electrode layer mainly made of, e.g. Mo is not less than 0.05λ, thereby improving a withstand voltage of the acoustic wave device. The thickness of the second electrode layer mainly made of, e.g Al is not less than 0.025λ reduces a resistance of the IDT electrode, accordingly providing the acoustic wave device with a small insertion loss.

### BRIEF DESCRIPTION OF DRAWINGS

FIG. 1 is a schematic sectional view of an acoustic wave device according to Exemplary Embodiment 1 of the present invention.

FIG. 2 is a graph showing characteristics of the acoustic wave device.

FIG. 3 is a graph showing characteristics of the acoustic wave device.

FIG. 4 is a schematic sectional view of another acoustic wave device.

FIG. 5 is a graph showing characteristics of the acoustic wave device.

FIG. 6 is a schematic sectional view of still another acoustic wave device.

FIG. 7 shows an example of a piezoelectric body and an IDT electrode of the acoustic wave device.

FIG. 8 is a schematic sectional view of an acoustic wave device according to Exemplary Embodiment 2 of the present invention.

FIG. 9 is a graph showing characteristics of the acoustic wave device.

FIG. 10 is a schematic sectional view of another acoustic wave device.

FIG. 11 is a graph showing characteristics of the acoustic wave device.

FIG. 12 is a schematic sectional view of still another acoustic wave device.

FIG. 13A shows a process for producing the acoustic wave device.

FIG. 13B shows a process for producing the acoustic wave device.

FIG. 13C shows a process for producing the acoustic wave device.

FIG. 13D shows another process for producing the acoustic wave device.

FIG. 13E shows a process for producing the acoustic wave device.

FIG. 13F shows a process for producing the acoustic wave device.

FIG. 13G shows a process for producing the acoustic wave device.

FIG. 13H shows a process for producing the acoustic wave device.

FIG. 14A shows conditions to suppress spurious modes in the acoustic wave device.

FIG. 14B shows conditions to suppress spurious modes in the acoustic wave device.

FIG. 14C shows conditions to suppress spurious modes in the acoustic wave device.

FIG. 14D shows conditions to suppress spurious modes in the acoustic wave device.

FIG. 14E shows conditions to suppress spurious modes in the acoustic wave device.

FIG. 14F shows conditions to suppress spurious modes in the acoustic wave device.

FIG. 14G shows conditions to suppress spurious modes in the acoustic wave device.

FIG. 15 is a schematic sectional view of an acoustic wave device according to Exemplary Embodiment 3 of the present invention.

FIG. 16 is a graph showing characteristics of the acoustic wave device.

FIG. 17 is a graph showing characteristics of the acoustic wave device.

FIG. 18 is a schematic sectional view of another acoustic wave device.

FIG. 19 is a graph showing characteristics of the acoustic wave device.

FIG. 20 is a schematic sectional view of still another acoustic wave device.

FIG. 21 shows a piezoelectric body and an IDT electrode of the acoustic wave device.

FIG. 22 is a schematic sectional view of an acoustic wave device according to Exemplary Embodiment 4 of the present invention.

FIG. 23 is a graph showing characteristics of the acoustic wave device.

FIG. 24 is another schematic sectional view of the acoustic wave device.

FIG. 25 is a graph showing characteristics of the acoustic wave device.

FIG. 26 is a schematic sectional view of another acoustic wave device.

FIG. 27 is a schematic sectional view of an acoustic wave device according to Exemplary Embodiment 5 of the present invention.

FIG. 28 is a graph showing characteristics of the acoustic wave device.

FIG. 29 is a graph showing characteristics of the acoustic wave device.

FIG. 30 is a schematic sectional view of another acoustic wave device.

FIG. 31 is a graph showing characteristics of the acoustic wave device.

FIG. 32 is a schematic sectional view of still another acoustic wave device.

FIG. 33 shows a piezoelectric body and an IDT electrode of the acoustic wave device.

FIG. 34 is a schematic sectional view of an acoustic wave device according to Exemplary Embodiment 6 of the present invention.

FIG. 35 is a graph showing characteristics of the acoustic wave device.

FIG. 36 is a schematic sectional view of another acoustic wave device.

FIG. 37 is a graph showing characteristics of the acoustic wave device.

FIG. 38 is a schematic sectional view of still another acoustic wave device.

FIG. 39 is a schematic sectional view of a conventional acoustic wave device.

### DETAIL DESCRIPTION OF PREFERRED EMBODIMENTS

### Exemplary Embodiment 1

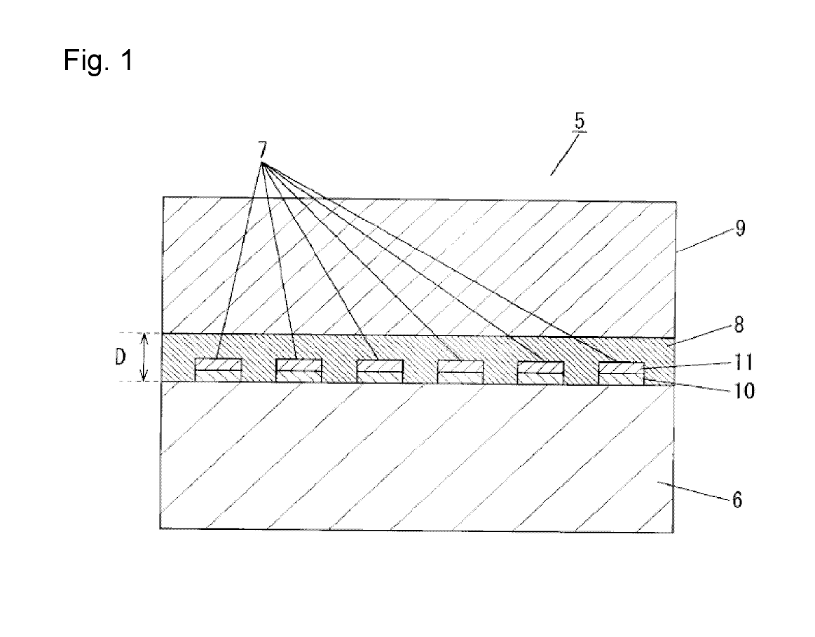

Exemplary Embodiment 1 of the present invention will be described with reference to drawings. FIG. 1 is a schematic sectional view of an acoustic wave device according to Exemplary Embodiment 1 (a schematic sectional view perpendicular to a direction in which electrode fingers of an IDT electrode extend).

As shown in FIG. 1, acoustic wave device 5 includes piezoelectric body 6. An IDT electrode 7 disposed on piezoelectric body 6 to excite main acoustic waves (such as shear horizontal waves) having a wavelength λ, and silicon oxide film 8 disposed on piezoelectric body 6 to cover IDT electrode 7. The silicon oxide film 8 has a thickness which is not less than 0.20λ and is less than 1λ. The wavelength λ of the main acoustic waves is twice the length of a pitch of electrode fingers of the IDT electrode. Acoustic wave device 5 further includes dielectric film 9 disposed on silicon oxide film 8. Dielectric film 9 allows transverse waves to propagate through the dielectric film faster than transverse waves propagating through silicon oxide film 8. Acoustic wave device 5 is a boundary wave device, which excites main acoustic waves while confining most of the energy in the boundary between piezoelectric body 6 and silicon oxide film 8.

Piezoelectric body 6 is made of a lithium niobate (LiNbO₃) substrate, but may alternatively be made of other piezoelectric single crystal medium, such as a crystal substrate or thin film thereof, a lithium tantalite (LiTaO₃) substrate or thin film thereof, or a potassium niobate (KNbO₃) substrate or thin film thereof.

In the case that piezoelectric body 6 is made of a lithium niobate substrate, the substrate preferably has an Euler angle (φ, θ, ψ) where −100°≦θ≦−60° to suppress spurious modes. As described in Japanese Patent Application No. 2009-251696, the Euler angle (φ, θ, ψ) of piezoelectric body 6 made of lithium niobate preferably satisfies the following relation: −100°≦θ≦−60°; 1.193φ−2°≦ψ≦1.193 φ+2°; ψ≦−2φ−3°; and −2φ+3°≦ψ where φ and θ are cut angles of piezoelectric body 6, and ψ is a propagation angle of the main acoustic waves on piezoelectric body 6 at IDT electrodes 7. The Euler angle within these ranges can suppress spurious modes around a frequency band where fast transverse waves are generated, while suppressing spurious modes caused by a Rayleigh wave.

IDT electrode 7 is an interdigital transducer electrode having a comb-shape in view from above acoustic wave device 5. IDT electrode 7 includes first electrode layer 10 mainly made of Mo and second electrode layer 11 mainly made of Al. First electrode layer 10 is disposed on piezoelectric body 6, and second electrode layer 11 is disposed on first electrode layer 10. First electrode layer 10 may contain, for example, Si, while second electrode layer 11 may contain, for example, Mg, Cu, or Si. This can improve the power resistance characteristics of IDT electrodes 7.

IDT electrode 7 has a total thickness not more than 0.15λ. First electrode layer 10 has a thickness not less than 0.05λ. Second electrode layer 11 has a thickness not less than 0.025λ.

Silicon oxide film 8 can improve frequency temperature characteristics of acoustic wave device 5 since silicon oxide film 8 is made of a medium having frequency temperature characteristics reverse to that of piezoelectric body 6. The thickness of silicon oxide film 8 is determined such that the velocity of the main acoustic waves is lower than the slowest transverse wave that propagates through piezoelectric body 6. This arrangement reduces leakage of the main acoustic waves toward piezoelectric body 6.

The thickness of silicon oxide film 8 is determined such that the frequency temperature characteristics of the main acoustic waves excited by IDT electrode 7 is not more than a predetermined value (30 ppm/° C.).

In the case that the thickness of silicon oxide film 8 ranges from 0.2λ to 0.5λ, the above-mentioned levels can be satisfied to reduce the leakage of the main acoustic waves and improves the frequency temperature characteristics.

The thickness of silicon oxide film 8 is defined as a distance D from the boundary between piezoelectric body 6 and silicon oxide film 8 to the upper surface of silicon oxide film 8 in the region where IDT electrode 7 is not disposed, and piezoelectric body 6 contacts silicon oxide film 8.

Dielectric film 9 is made of a medium which allows transverse waves to propagate through the dielectric film faster than transverse waves propagating through silicon oxide film 8. Dielectric film 9 can be made of, for example, diamond, silicon, silicon nitride, aluminum nitride, or aluminum oxide. Dielectric film 9 has a larger thickness than silicon oxide film 8 while the thickness is not less than the wavelength λ of the SH (shear horizontal) waves, the main acoustic waves. As a result, the main acoustic waves can be confined in acoustic wave device 5. The thickness of dielectric film 9 is preferably not more than 5λ to provide acoustic wave device 5 with a low profile.

Acoustic wave device 5 according to the present invention will be detailed below.

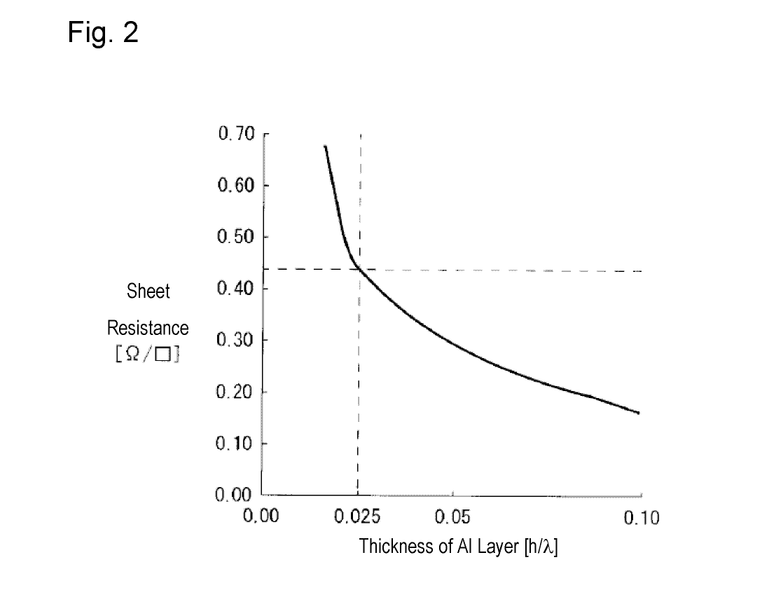

FIG. 2 shows the relation between the sheet resistance (Ω/□) of the entire portion of IDT electrode 7 and the thickness (λ) of second electrode layer 11 in the case that first electrode layer 10 is a Mo layer with a thickness of 0.05λ and an Al layer as second electrode layer 11 is disposed on the Mo layer. As shown in FIG. 2, in the case that the thickness of second electrode layer 11 is less than 0.025λ, the entire resistance of IDT electrode 7 is higher than 0.44Ω/□ with an inflection point. Thus, the resistance of IDT electrode 7 can be reduced by determining the thickness of second electrode layer 11 to be not less than 0.025λ, thereby reducing the insertion loss of acoustic wave device 5.

In the case that the thickness of second electrode layer 11 is not less than 0.025λ, the resistance of IDT electrodes 7 does not depend on the thickness of first electrode layer 10. This is because, in the case that the thickness of second electrode layer 11 made of Al is not less than 0.025λ, most of a current flowing through IDT electrodes 7 flows through second electrode layer 11.

As described above, in acoustic wave device 5, the unevenness in thickness of silicon oxide film 8 can be reduced by setting the total thickness of IDT electrode 7 to not more than 0.15λ. The thickness of first electrode layer 10 mainly made of Mo not less than 0.05λ can improve the power resistance characteristics of the acoustic wave device. The thickness of second electrode layer 11 mainly made of Al not less than 0.025λ can reduce the resistance of IDT electrode 7, hence reducing the insertion loss of acoustic wave device 5.

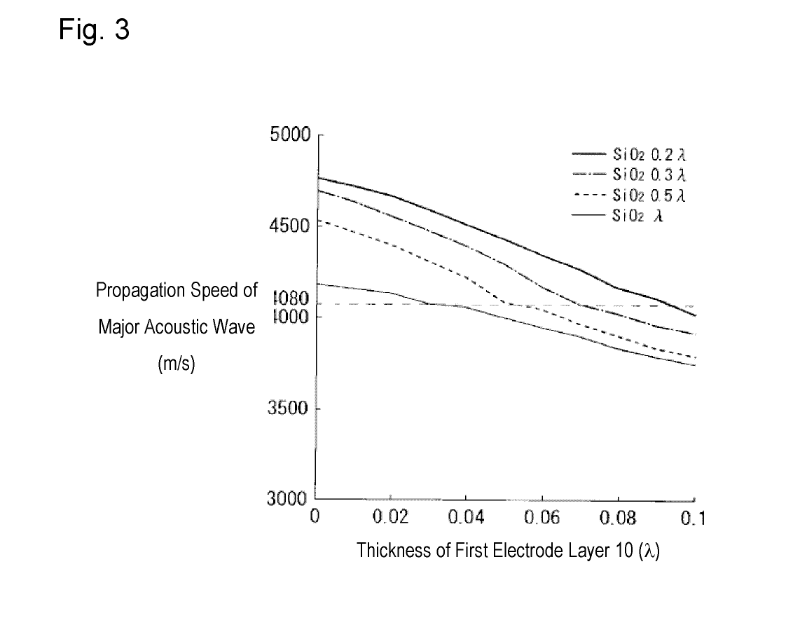

FIG. 3 shows the relation between the thickness (λ) of the first electrode layer and the propagation speed (m/s) of the main acoustic waves that propagate through IDT electrodes 7 in the case that piezoelectric body 6 is a 25 degree rotated Y-cut X-propagation lithium niobate substrate, dielectric film 9 is made of silicon nitride (SiN) with a thickness of 1λ, and the thickness D of silicon oxide film 8 is changed in a range from 0.2λ to 1λ. It is assumed that the silicon oxide film has a flat upper surface, and second electrode layer 11 has a thickness of 0.025λ. As the thickness of second electrode layer 11 becomes larger than this, the propagation speed of the main acoustic waves becomes slightly smaller. If the thickness is not less than 1λ, the thickness of dielectric film 9 does not affect the propagation speed (m/s) of the main acoustic waves that propagate through IDT electrodes 7. The propagation speed of the main acoustic waves shown in FIG. 3 represents the propagation speed at the antiresonant frequency of the main acoustic waves. This is applied to other figures showing the propagation speed of the main acoustic waves. When we focus on the energy loss of the main acoustic waves, it can be considered to be important to focus on the energy loss at both the resonant and antiresonant frequencies of the main acoustic waves. However, the propagation speed of the main acoustic waves is higher at the antiresonant frequency than at the resonant frequency. For this reason, the antiresonant frequency can be used to compare the propagation speed between the main acoustic waves and bulk waves in terms of the energy loss.

As shown in FIG. 3, in the case that the thickness of silicon oxide film 8 is 0.2λ, if the thickness of first electrode layer 10 is not less than 0.093λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, if the thickness of first electrode layer 10 is not less than 0.068λ, the propagation speed of the main acoustic waves that propagate through IDT electrodes 7 is lower than the propagation speed (4080 m/s) of a slow transverse wave (bulk wave) that propagates through piezoelectric body 6. This can reduce the energy loss of the main acoustic waves due to bulk wave radiation.

In the case that the thickness of silicon oxide film 8 is 0.5λ, if the thickness of first electrode layer 10 is not less than 0.05λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is λ, if the thickness of first electrode layer 10 is not less than 0.03λ, the propagation speed of the main acoustic waves that propagate through IDT electrodes 7 is lower than the propagation speed (4080 m/s) of the slowest transverse wave (a bulk wave) that propagate through piezoelectric body 6. This can reduce the energy loss of the main acoustic waves due to bulk wave radiation.

Thus, the propagation speed of the main acoustic waves that propagate through IDT electrodes 7 is lower than the propagation speed (4080 m/s) of the slowest transverse wave (bulk waves) that propagate through piezoelectric body 6, thereby reducing the energy loss of the main acoustic waves due to bulk wave radiation in the following conditions: the thickness of first electrode layer 10 is not less than 0.093λ in the case that the thickness of silicon oxide film 8 is not less than 0.2λ and is less than 0.3λ; the thickness of first electrode layer 10 is not less than 0.068λ in the case that the thickness of silicon oxide film 8 is not less than 0.3λ and is less than 0.5λ; the thickness of first electrode layer 10 is not less than 0.05λ in the case that the thickness of silicon oxide film 8 is not less than 0.5λ and is less than 1λ; and the thickness of first electrode layer 10 is not less than 0.03λ in the case that the thickness of silicon oxide film 8 is λ.

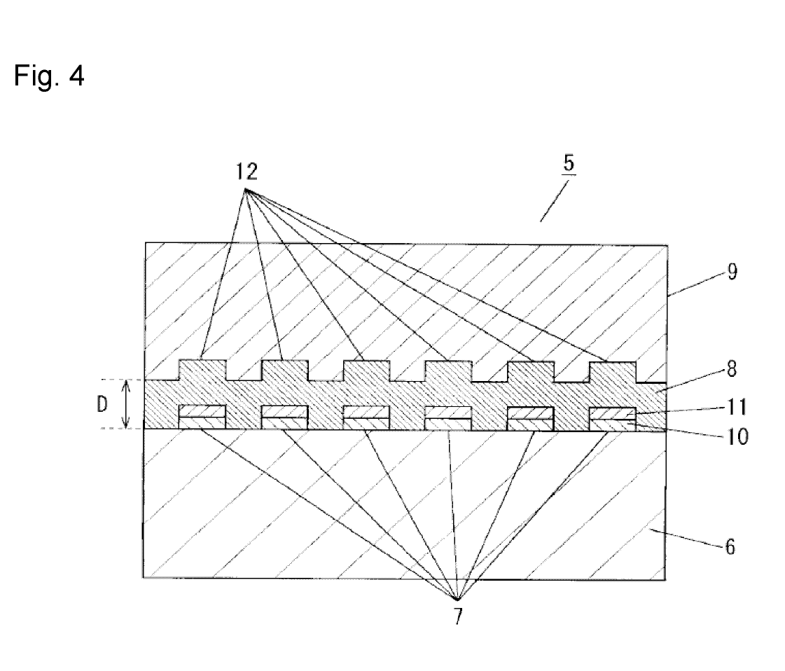

FIG. 4 is a schematic sectional view of another acoustic wave device according to Exemplary Embodiment 1 (a schematic sectional view perpendicular to a direction in which the electrode fingers of the IDT electrode extend). The device shown in FIG. 4 is different from the device shown in FIG. 1 in that projections 12 are provided on the upper surface of silicon oxide film 8 above the electrode fingers of IDT electrode 7.

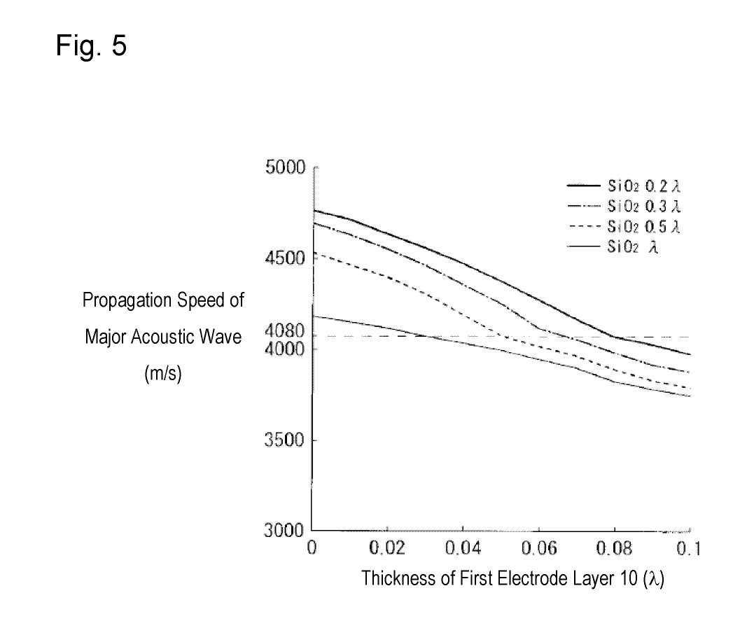

FIG. 5 shows the relation between the thickness (λ) of the first electrode layer and the propagation speed (m/s) of the main acoustic waves that propagate through IDT electrodes 7 in the case that projections 12 have the same shape in cross section as the electrode fingers of IDT electrodes 7; piezoelectric body 6 is a 25 degree rotated Y-cut X-propagation lithium niobate substrate; dielectric film 9 is made of silicon nitride (SiN) with a thickness of 1λ; and the thickness D of silicon oxide film 8 is changed in a range from 0.2λ to 1λ. It is assumed that second electrode layer 11 has a thickness of 0.025λ. As the thickness of second electrode layer 11 becomes larger than this, the propagation speed of the main acoustic waves becomes slightly smaller. If the thickness it is not less than 1λ, the thickness of dielectric film 9 does not affect the propagation speed (m/s) of the main acoustic waves that propagate through IDT electrodes 7.

As shown in FIG. 5, in the case that the thickness of silicon oxide film 8 is 0.2λ, if the thickness of first electrode layer 10 is not less than 0.08λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, if the thickness of first electrode layer 10 is not less than 0.066λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.5λ, if the thickness of first electrode layer 10 is not less than 0.051λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is λ, if the thickness of first electrode layer 10 is not less than 0.03λ, the propagation speed of the main acoustic waves that propagate through IDT electrodes 7 is lower than the propagation speed (4080 m/s) of the slowest transverse wave (bulk waves) that propagate through piezoelectric body 6. This can reduce the energy loss of the main acoustic waves due to bulk wave radiation.

Projections 12 provided on the upper surface of silicon oxide film 8 above the fingers of IDT electrodes 7 slightly reduce the propagation speed of the main acoustic wave that propagate through IDT electrode 7. Thus, even if first electrode layer 10 has a small thickness, the energy loss of the main acoustic waves due to bulk wave radiation is lower than the device having no projection 12.

Thus, projections 12 on the upper surface of silicon oxide film 8 above the fingers of IDT electrodes 7 can reduce the energy loss of the main acoustic waves due to bulk wave radiation under the following conditions. The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.08λ in the case that the thickness of silicon oxide film 8 is not less than 0.2λ and is less than 0.3λ; the thickness of first electrode layer 10 is not less than 0.066λ in the case that the thickness of silicon oxide film 8 is not less than 0.3λ and is less than 0.5λ; the thickness of first electrode layer 10 is not less than 0.051λ in the case that the thickness of silicon oxide film 8 is not less than 0.5λ and is less than 1λ; and the thickness of first electrode layer 10 is not less than 0.03λ in the case that the thickness of silicon oxide film 8 is λ.

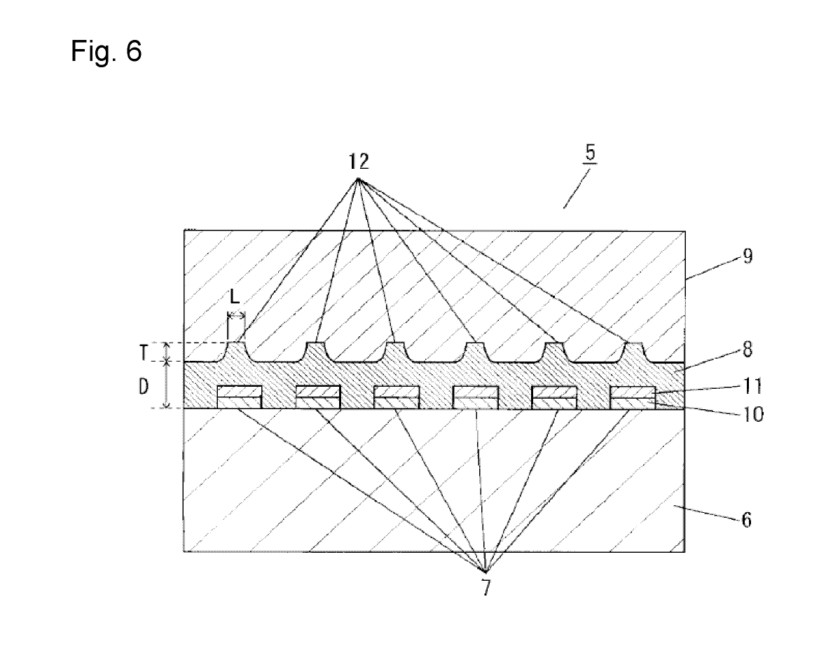

As shown in FIG. 6, in the case that a cross section of projection 12 has a smaller area than a cross section of the electrode finger of IDT electrodes 7, the propagation speed of the main acoustic waves propagating through first electrode layer 10 has a value between the values shown in FIGS. 3 and 5.

Projections 12 will be detailed below.

Projections 12 of silicon oxide film 8 are preferably curved concavely from the top to the bottom. The width L of the top portion of projection 12 is defined as the distance between two points where either the concave curves or extension lines thereof intersects with a straight line which is parallel to the upper surface of piezoelectric body 6 and which passes the top of the projection. In this case, the width L of the top portion is smaller than the width of the fingers of IDT electrodes 7. This structure allows a mass added to silicon oxide film 8 at projections 12 to change continuously and gradually and prevents unwanted reflections due to the shape of silicon oxide film 8, thereby improving the electrical characteristics of acoustic wave device 5.

The width of the top portions of projections 12 is preferably one half or less of the width of the fingers of IDT electrode 7. The center positions of the top portions of projections 12 are preferably substantially directly above the center positions of the electrode fingers. This further improves the reflectance at the electrode fingers due to the mass addition effect, thereby improving the electrical characteristics of acoustic wave device 5.

The height T of projections 12 and the total thickness h of IDT electrode 7 may preferably satisfy 0.03λ<T≦h. According to a study of the relation between the height T from the bottom portion to the top portion of projections 12 of silicon oxide film 8 and the electrical characteristics, the reflectance is very high in the case that the height T is higher than 0.03λ, and silicon oxide film 8 has a flat surface. If the height T is larger than the thickness h of IDT electrodes 7, an additional process is required to produce silicon oxide film 8, thereby complicating the production method.

Second electrode layer 11 preferably contacts a part of side surfaces of first electrode layer 10. This arrangement prevents silicon oxide film 8 from peeling off from piezoelectric body 6.

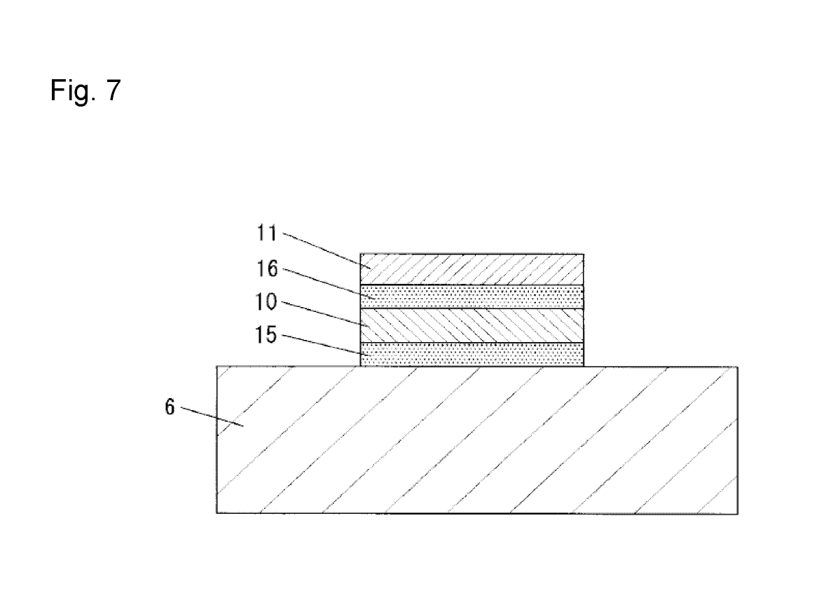

As shown in FIG. 7, an adhesive layer composed of a Ti layer, a TiN layer, a Cr layer, or a NiCr layer between piezoelectric body 6 and first electrode layer 10 can prevent IDT electrode 7 from peeling off from piezoelectric body 6.

An adhesive layer composed of a Ti layer, a TiN layer, a Cr layer, or a NiCr layer between first electrode layer 10 and second electrode layer 11 as shown in FIG. 7 can improve the power resistance characteristics of acoustic wave device 5.

### Exemplary Embodiment 2

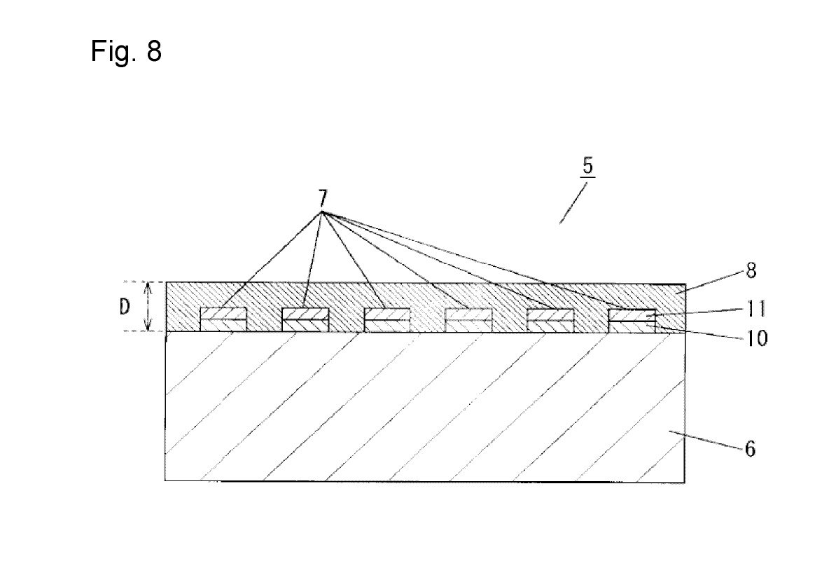

Exemplary Embodiment 2 of the present invention will be described with reference to drawings. FIG. 8 is a schematic sectional view of an acoustic wave device according to Exemplary Embodiment 2 (a schematic sectional view perpendicular to a direction in which electrode fingers of the IDT electrode extend). Components identical to those of Embodiment 1 are denoted by the same reference numerals, and their detailed description will be omitted.

In FIG. 8, acoustic wave device 5 does not include dielectric film 9 of Embodiment 1, and is a surface wave device for exciting main acoustic waves by distributing energy either to the surface of piezoelectric body 6 or to silicon oxide film 8.

IDT electrode 7 has a total thickness not more than 0.15λ. First electrode layer 10 has a thickness not less than 0.03λ. Second electrode layer 11 has a thickness not less than 0.025λ.

The thickness of silicon oxide film 8 is determined such that the frequency temperature characteristics of the main acoustic waves excited by IDT electrode 7 can be not more than a predetermined value (10 ppm/° C.).

In the case that the thickness of silicon oxide film 8 ranges from 0.2λ to 0.5λ, the above-mentioned levels can be satisfied, thereby achieving both prevention of leakage of the main acoustic waves and improvement of the frequency temperature characteristics.

Similar to Embodiment 1, if the thickness of second electrode layer 11 is less than 0.025λ, the entire resistance of IDT electrode 7 is high. Thus, the resistance of IDT electrode 7 can be reduced by setting the thickness of second electrode layer 11 to be not less than 0.025λ, thereby reducing the insertion loss of acoustic wave device 5.

As described above, in acoustic wave device 5, the unevenness in thickness of silicon oxide film 8 can be reduced by setting the total thickness of IDT electrode 7 to be not more than 0.15λ. The thickness of first electrode layer 10 mainly made of Mo not less than 0.03λ can improve the power resistance characteristics of acoustic wave device 5. The thickness of second electrode layer 11 mainly made of Al not less than 0.025λ can reduce the resistance of IDT electrode 7. As a result, the insertion loss of acoustic wave device 5 can be reduced.

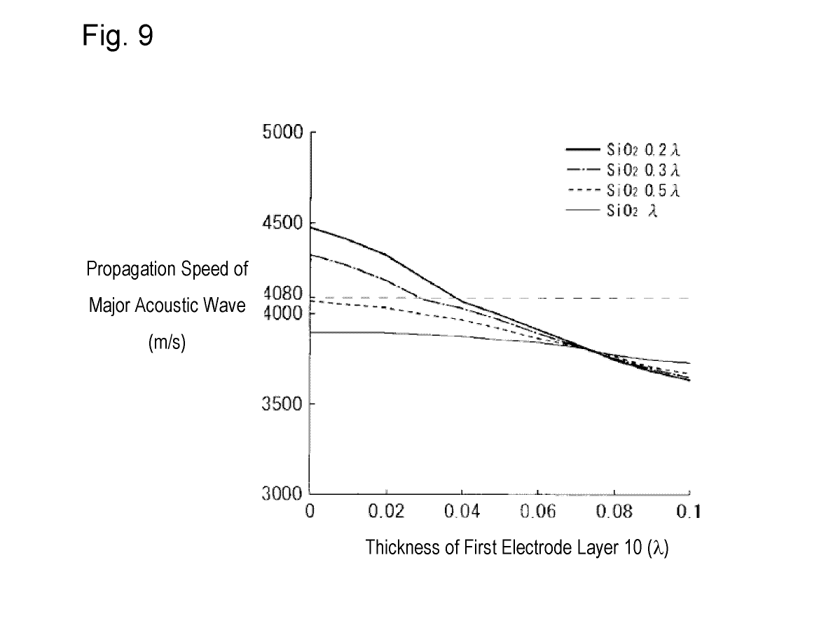

FIG. 9 shows the relation between the thickness (λ) of the first electrode layer and the propagation speed (m/s) of the main acoustic waves that propagate through IDT electrodes 7 in the case that piezoelectric body 6 is a 25 degree rotated Y-cut X-propagation lithium niobate substrate; and the thickness D of silicon oxide film 8 is changed in the range from 0.2λ to 1λ. It is assumed that the silicon oxide film has a flat upper surface, and second electrode layer 11 has a thickness of 0.025λ. As the thickness of second electrode layer 11 becomes larger than this, the propagation speed of the main acoustic waves becomes slightly smaller.

As shown in FIG. 9, in the case that the thickness of silicon oxide film 8 is 0.2λ, if the thickness of first electrode layer 10 is not less than 0.038λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, if the thickness of first electrode layer 10 is not less than 0.03λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is not less than 0.5λ, even if the device does not include first electrode layer 10, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation. This acoustic wave device is not within a scope of the present invention.

Thus, the propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions; the thickness of first electrode layer 10 is not less than 0.038λ in the case that the thickness of silicon oxide film 8 is not less than 0.2λ and is less than 0.3λ; and the thickness of first electrode layer 10 is not less than 0.03λ in the case that the thickness of silicon oxide film 8 is not less than 0.3λ and is less than 0.5λ.

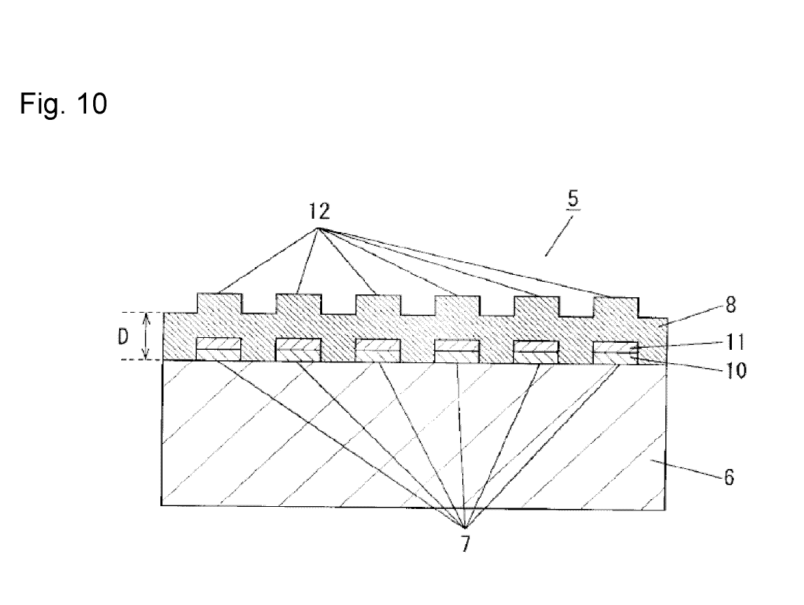

FIG. 10 is a schematic sectional view of another acoustic wave device according to Embodiment 2 (a schematic sectional view perpendicular to a direction in which electrode fingers of the IDT electrode). The device shown in FIG. 10 is different from the device shown in FIG. 8 in that projections 12 are provided on the upper surface of silicon oxide film 8 above the electrode fingers of IDT electrode 7.

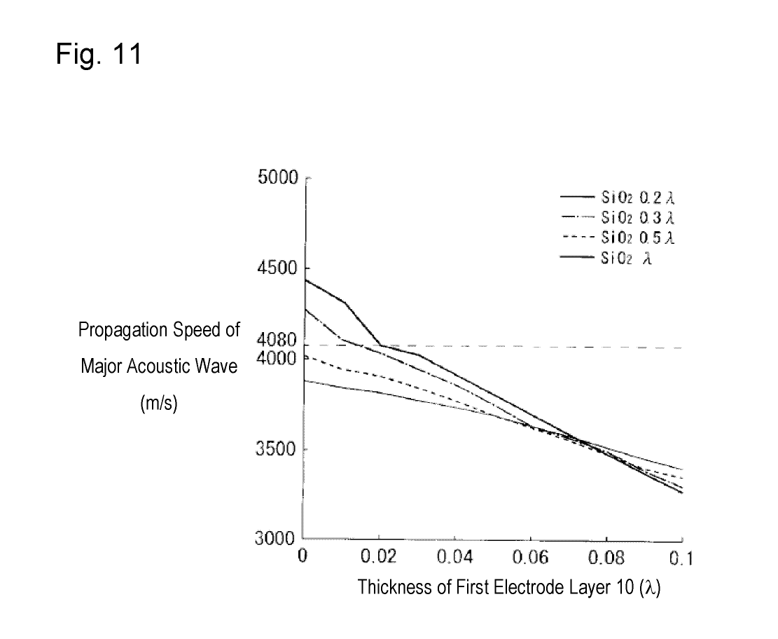

FIG. 11 shows the relation between the thickness (λ) of the first electrode layer and the propagation speed (m/s) of the main acoustic waves that propagate through IDT electrodes 7 in the case that projections 12 have the same shape in cross section as the electrode fingers of IDT electrodes 7; piezoelectric body 6 is a 25 degree rotated Y-cut X-propagation lithium niobate substrate; and the thickness D of silicon oxide film 8 is changed in the range from 0.2λ to 1λ. It is assumed that second electrode layer 11 has a thickness of 0.025λ. As the thickness of second electrode layer 11 becomes larger than this, the propagation speed of the main acoustic waves becomes slightly smaller.

As shown in FIG. 11, in the case that the thickness of silicon oxide film 8 is 0.2λ, if the thickness of first electrode layer 10 is not less than 0.02λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, if the thickness of first electrode layer 10 is not less than 0.014λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is not less than 0.5λ even if the device does not include first electrode layer 10, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation. This acoustic wave device is not with a scope of the present invention.

Projections 12 thus provided on the upper surface of silicon oxide film 8 above the electrode fingers of IDT electrodes 7 slightly reduce the propagation speed of the main acoustic waves that propagate through IDT electrode 7. Thus, even if first dielectric layer 10 has a small thickness, the energy loss of the main acoustic waves due to bulk wave radiation is lower than the device which does not include projections 12.

Thus, projections 12 on the upper surface of silicon oxide film 8 above the electrode fingers of IDT electrodes 7 can reduce the energy loss of the main acoustic waves due to bulk wave radiation under the following conditions. The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.02λ in the case that the thickness of silicon oxide film 8 is not less than 0.2λ and is less than 0.3λ; and the thickness of first electrode layer 10 is not less than 0.014λ in the case that the thickness of silicon oxide film 8 is not less than 0.3λ and is less than 0.5λ.

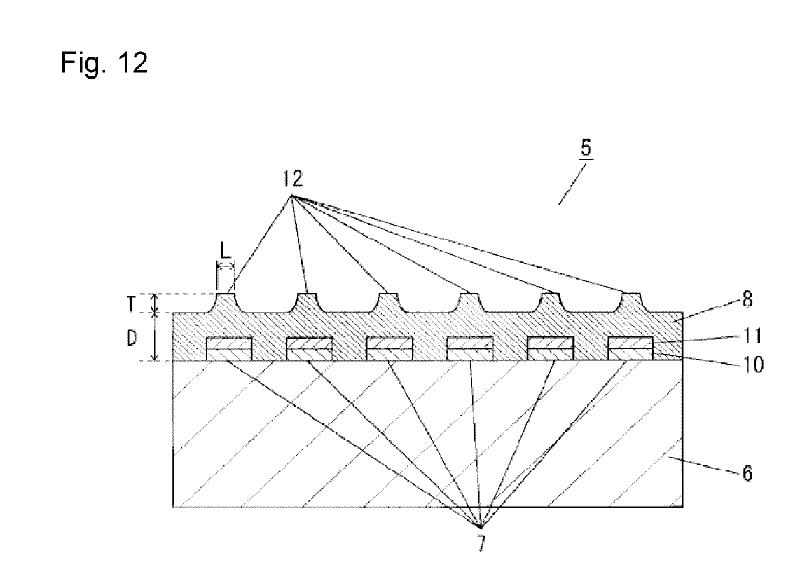

As shown in FIG. 12, in the case that a cross section of projection 12 has a smaller area than a cross section of the electrode finger of IDT electrodes 7, the propagation speed of the main acoustic waves propagating through first electrode layer 10 has a value between the values shown in FIGS. 9 and 10.

Projections 12 will be detailed below.

Projections 12 of silicon oxide film 8 are preferably curved concavely from the top to the bottom. The width L of the top portion of projection 12 is defined as the distance between two points where either the concave curves or extension lines thereof intersects with a straight line which is parallel to the upper surface of piezoelectric body 6 and which passes the top of the projection. In this case, the width L of the top portion is smaller than the width of the fingers of IDT electrodes 7. This structure allows a mass added to silicon oxide film 8 at projections 12 to change continuously and gradually and prevents unwanted reflections due to the shape of silicon oxide film 8, thereby improving the electrical characteristics of acoustic wave device 5.

The width of the top portions of projections 12 is preferably one half or less of the width of the fingers of IDT electrode 7. The center positions of the top portions of projections 12 are preferably substantially directly above the center positions of the electrode fingers. This further improves the reflectance at the electrode fingers due to the mass addition effect, thereby improving the electrical characteristics of acoustic wave device 5.

The height T of projections 12 and the total thickness h of IDT electrode 7 may preferably satisfy 0.03λ<T≦h. According to a study of the relation between the height T from the bottom portion to the top portion of projections 12 of silicon oxide film 8 and the electrical characteristics, the reflectance is very high in the case that the height T is higher than 0.03λ, and silicon oxide film 8 has a flat surface. If the height T is larger than the thickness h of IDT electrodes 7, an additional process is required to produce silicon oxide film 8, thereby complicating the production method.

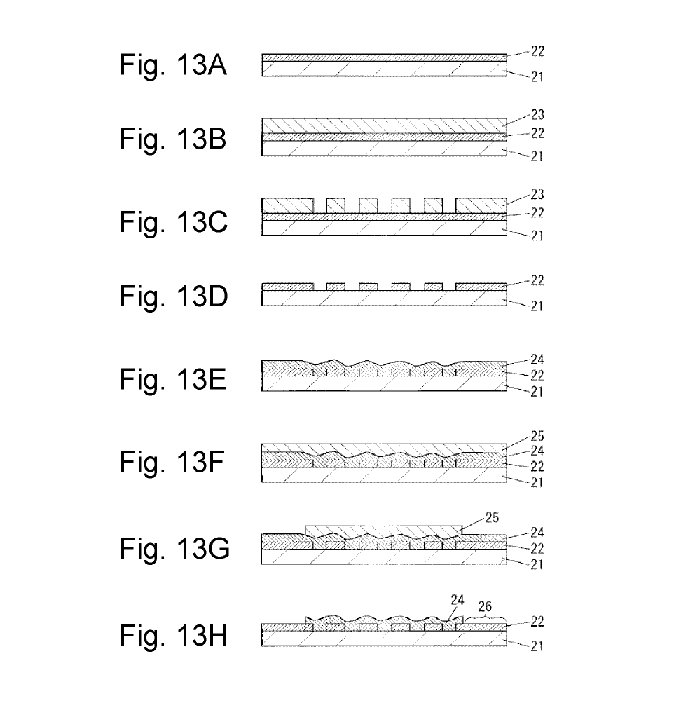

FIGS. 13A to 1311 illustrate processes for producing acoustic wave device 5 including projections 12 according to Embodiment 1 of the invention.

First, as shown in FIG. 13A, electrode film 22 to be IDT electrode and/or reflectors 21 by, for example, depositing or sputtering Al or an Al alloy on the upper surface of piezoelectric body.

Next, as shown in FIG. 13B, resist film 23 is formed on the upper surface of electrode film 22.

Then, as shown in FIG. 13C, resist film 23 is processed to have a predetermined shape by, for example, exposure and development.

Then, as shown in FIG. 13D, electrode film 22 is processed to have a predetermined shape to form the IDT electrode or the reflectors by, for example, dry etching. Then, resist film 23 is removed.

Then, as shown in FIG. 13E, silicon oxide film 24 is formed by, for example, depositing or sputtering silicon oxide (SiO₂) to cover electrode film 22. To provide the aforementioned projections on silicon oxide film 24, so-called bias-sputtering is used, in which a film is formed by sputtering while a bias is applied on piezoelectric body 21.

A target of silicon oxide is sputtered to deposit silicon oxide film 24 on piezoelectric body 21. At this moment, a part of silicon oxide film 24 on piezoelectric body 21 is bias-sputtered. Thus, silicon oxide film 24 is partially removed while being deposited to control its shape. As methods for controlling the shape of silicon oxide film 24, the ratio of the bias applied to piezoelectric body 21 to the sputtering power while silicon oxide film 24 is being deposited is changed, or starting film formation without applying a bias to piezoelectric body 21, and applying a bias midway through the film formation. In these cases, the temperature of piezoelectric body 21 is also controlled.

Then, as shown in FIG. 13F, resist film 25 is formed on the surface of silicon oxide film 24.

Then, as shown in FIG. 13G, resist film 25 is processed to have a predetermined shape by, for example, exposure and development.

Then, as shown in FIG. 13H, a portion of a dielectric film that is not required by silicon oxide film 24 such as pad 26 for extracting electrical signals is removed by, for example, dry etching, and then, resist film 25 is removed.

Finally, piezoelectric body 21 is diced into individual parts to obtain acoustic wave device 5.

As described above, the inventors of the present invention were confirmed that silicon oxide film 8 can be formed to have a predetermined shape by using bias sputtering under optimum conditions of its formation.

It is understood that adhesive layers 15 and 16 of Embodiment 1 can be applied to the IDT electrode of Embodiment 2.

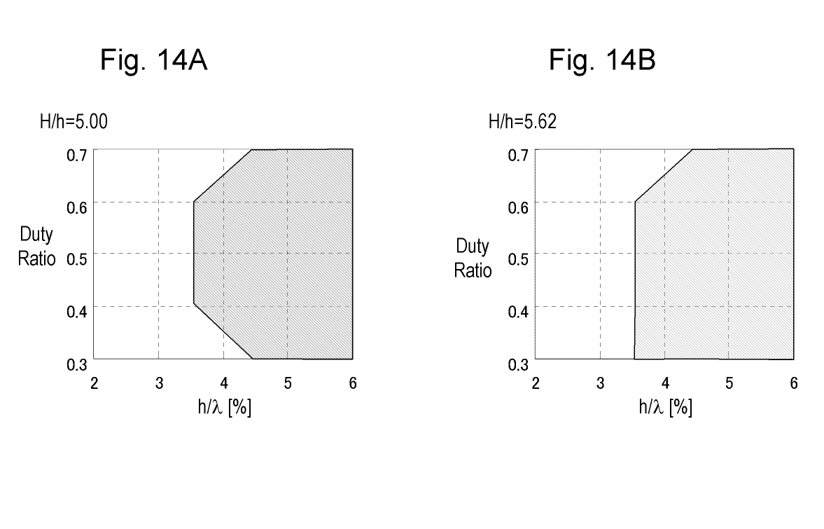

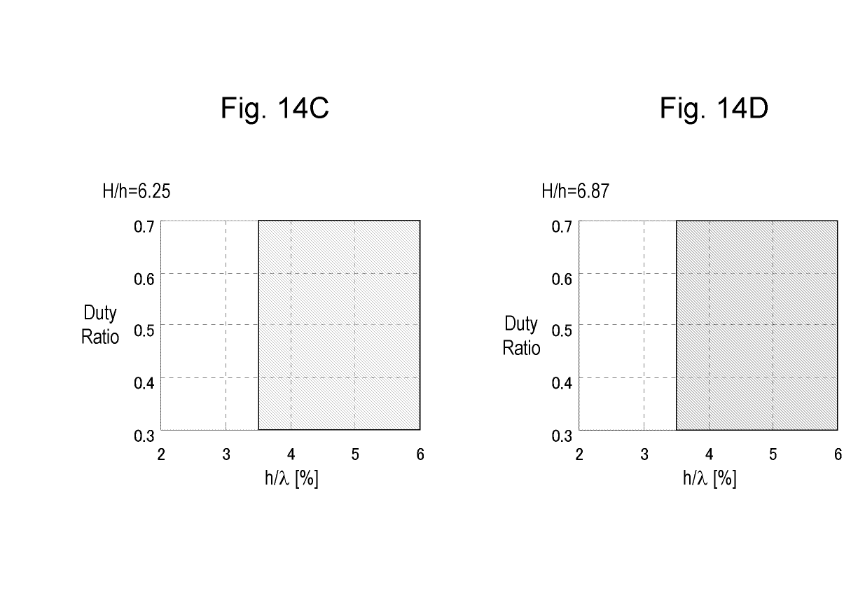

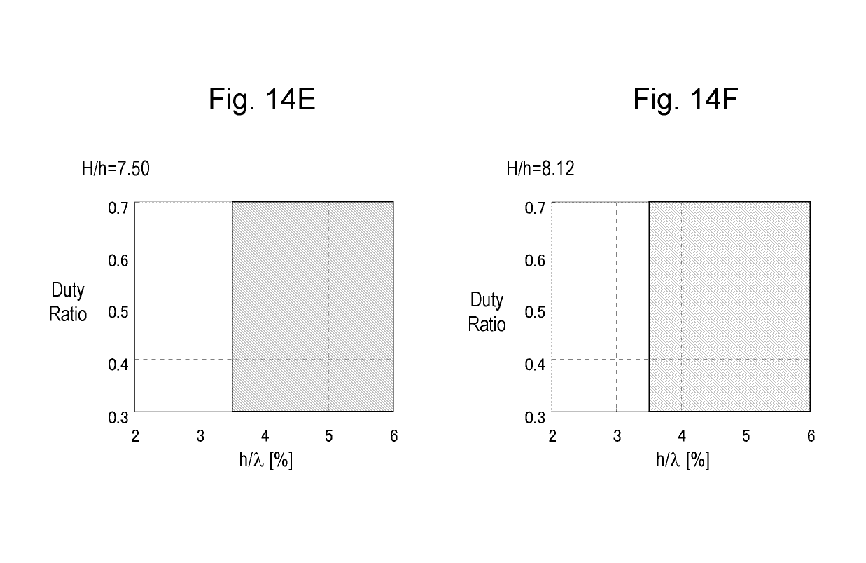

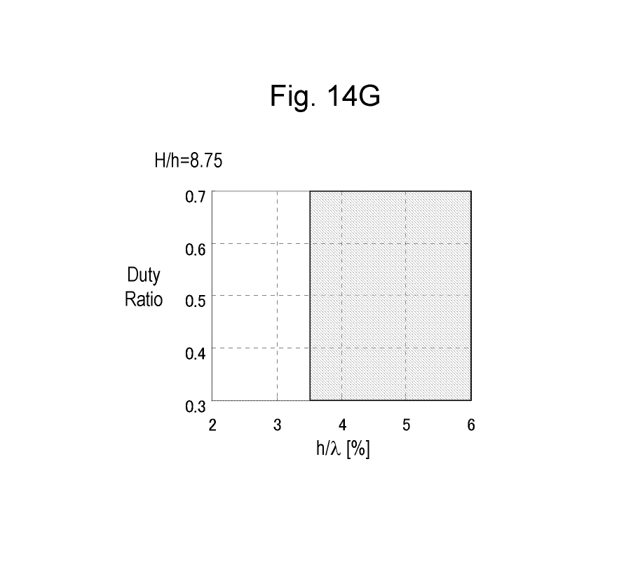

According to Embodiment 2, in the case that piezoelectric body 6 has an Euler angle (φ, θ, ψ) where −10°≦φ≦10°, 33°≦θ≦43°, and −10°≦ψ≦10°, the main acoustic waves to be excited by IDT electrodes 7 are Rayleigh waves. When using this Euler angle, the frequency band including resonant and antiresonant frequencies may not be included in a stopband in a short-circuit grating of IDT electrodes 7. As a result, spurious resonances occur in the resonant and antiresonant frequencies of IDT electrodes 7. To avoid this, it is necessary for IDT electrodes 7 to have a large reflection coefficient. It was found that the large reflection coefficient can be achieved when the relation of the thickness H of silicon oxide film 8, the thickness h of first electrode layer 10 made of Mo, and the ratio (duty ratio) η of the width of the electrode fingers to the pitch of IDT electrode 7 corresponds to the regions shown in FIGS. 14A to 14G.

FIGS. 14A to 14G show the regions corresponding to the values of the duty ratio (vertical axis) and the normalized thickness h/λ (%) (horizontal axis) of first electrode layer 10 when the stopband in a short-circuit grating of IDT electrodes 7 is not less than the antiresonant frequency. More specifically, FIG. 14A shows the case with the ratio H/h of 5.00; FIG. 14B shows the case with the ratio H/h of 5.62; FIG. 14C shows the case with the ratio H/h of 6.25; FIG. 14C shows the case with the ratio H/h of 6.87; in FIG. 14E shows the case with the ratio H/h of 7.50; FIG. 14F shows the case with the ratio H/h of 8.12; and FIG. 14G shows the case with the ratio H/h of 8.75.

As shown in FIGS. 14A to 14C, in the case that H/h is not less than 5.00 and is less than 6.25 and that h/λ is not less than 4.5%, the stopband of the short-circuit grating of IDT electrode 7 is less than the antiresonant frequency if the duty ratio of first electrode layer 10 is not less than 0.3 and is less than 0.4 or if the duty ratio of first electrode layer 10 is not less than 0.6 and is less than 0.7. This reduces spurious resonances occurring in the resonant and antiresonant frequencies of IDT electrodes 7. In the case that H/h is not less than 5.00 and is less than 6.25 and that h/λ is not less than 3.5%, the stopband in the short-circuit grating of IDT electrodes 7 is not less than the antiresonant frequency if the duty ratio of first electrode layer 10 is not less than 0.4 and is less than 0.6. This reduces spurious resonances occurring in the resonant and antiresonant frequencies of IDT electrodes 7.

As shown in FIGS. 14C to 14G, in the case that H/h ranges from 6.25 to 8.75, the stopband in the short-circuit grating of IDT electrodes 7 is not less than the antiresonant frequency if h/λ is not less than 3.5%. This reduces spurious resonances occurring in the resonant and antiresonant frequencies of IDT electrodes 7.

### Exemplary Embodiment 3

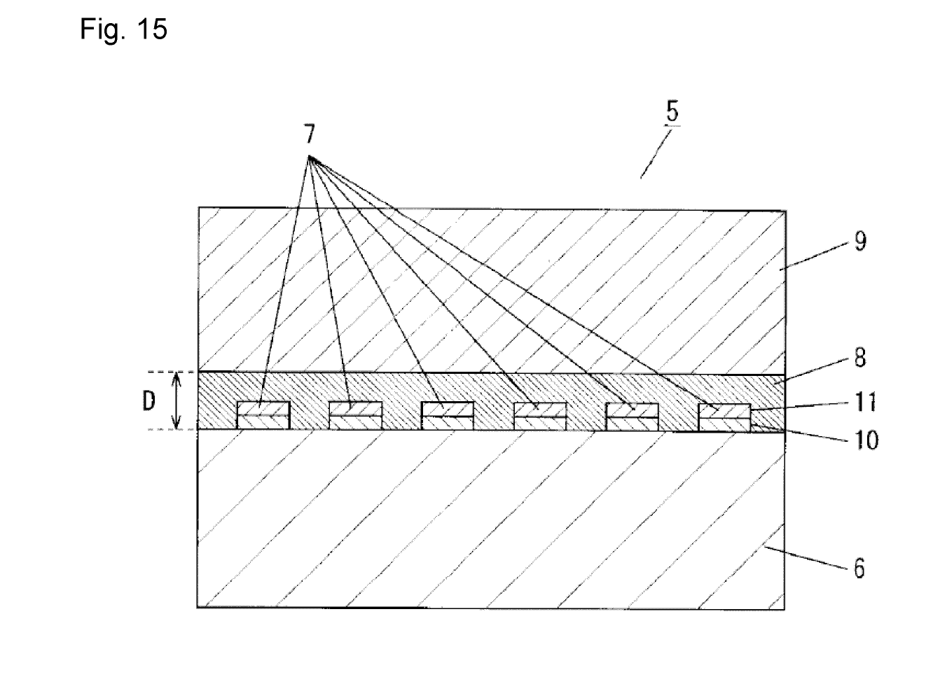

Exemplary Embodiment 3 of the present invention will be described with reference to drawings. FIG. 15 is a schematic sectional view of an acoustic wave device according to Exemplary Embodiment 3 (a schematic sectional view perpendicular to a direction in which electrode fingers of an IDT electrode extend).

The device according to Embodiment 3 id different from the device according to Embodiment 1 in that first electrode layer 10 is mainly made of W (tungsten).

In FIG. 15, acoustic wave device 5 includes piezoelectric body 6, IDT electrode 7 disposed on piezoelectric body 6 to excite main acoustic waves (such as shear horizontal waves) having a wavelength λ; and silicon oxide film 8 disposed on piezoelectric body 6 to cover IDT electrodes 7. Silicon oxide film 8 has a thickness ranging from 0.20λ to 0.50λ. Acoustic wave device 5 further includes dielectric film 9 disposed on silicon oxide film 8. Dielectric film 9 allows transverse waves to propagate through the dielectric film faster than transverse waves propagating through silicon oxide film 8. Acoustic wave device 5 is a boundary wave device which excites main acoustic waves while confining most of the energy in the boundary between piezoelectric body 6 and silicon oxide film 8.

Piezoelectric body 6 is made of a lithium niobate (LiNbO₃) substrate, but may alternatively be made of other piezoelectric single crystal medium, such as a crystal substrate or thin film thereof, a lithium tantalite (LiTaO₃) substrate or thin film thereof, or a potassium niobate (KNbO₃) substrate or thin film thereof.

In the case that piezoelectric body 6 is made of a lithium niobate substrate, the substrate preferably has an Euler angle (φ, θ, ψ) where −100°≦θ≦−60° in order to suppress spurious modes. As described in Japanese Patent Application No. 2009-251696, the Euler angle (φ, θ, ψ) of piezoelectric body 6 made of lithium niobate preferably satisfies the following ranges: −100°≦θ≦−60°; 1.193φ−2°≦ψ≦1.194φ+2°; ψ≦−2φ−3°; and −2φ+3°≦ψ where φ and θ are the cut angles of piezoelectric body 6, and ψ is the propagation angle of the main acoustic waves in IDT electrodes 7 on piezoelectric body 6. The Euler angle in these ranges can suppress the spurious modes in the vicinity of the frequency band where fast transverse waves are generated, while suppressing spurious modes caused by a Rayleigh wave.

IDT electrode 7 is an interdigital transducer electrode which has a comb-shape in view from above acoustic wave device 5. IDT electrode 7 includes first electrode layer 10 mainly made of W (tungsten) and second electrode layer 11 mainly made of Al (aluminum). First electrode layer 10 is disposed on piezoelectric body 6, and second electrode layer 11 is disposed on first electrode layer 10. First electrode layer 10 may contain, for example, Si, whereas second electrode layer 11 may contain, for example, Mg, Cu, or Si. This can improve the power resistance characteristics of IDT electrodes 7.

IDT electrode 7 has a total thickness not more than 0.15λ. First electrode layer 10 has a thickness not less than 0.03λ. Second electrode layer 11 has a thickness not less than 0.026λ.

Silicon oxide film 8 is made of a medium having frequency temperature characteristics reverse to those of piezoelectric body 6, thereby improving frequency temperature characteristics of acoustic wave device 5. The thickness of silicon oxide film 8 is determined such that the main acoustic waves have a lower velocity than the slowest transverse wave that propagate through piezoelectric body 6. This reduces leakage of the main acoustic waves toward piezoelectric body 6.

The thickness of silicon oxide film 8 is determined such that the frequency temperature characteristics of the main acoustic waves excited by IDT electrode 7 can be not more than a predetermined value (30 ppm/° C.).

In the case that the thickness of silicon oxide film 8 ranges from 0.2λ to 0.5λ, the above-mentioned levels can be satisfied, thereby achieving both prevention of leakage of the main acoustic waves and improvement of the frequency temperature characteristics.

The thickness of silicon oxide film 8 in this case is defined as a distance D from the boundary between piezoelectric body 6 and silicon oxide film 8 to the upper surface of silicon oxide film 8 in the region where IDT electrode 7 are not disposed and piezoelectric body 6 contacts silicon oxide film 8.

Dielectric film 9 is made of a medium which allows transverse waves to propagate through the dielectric film 9 faster than the transverse waves propagating through silicon oxide film 8. Dielectric film 9 can be made of, for example, diamond, silicon, silicon nitride, aluminum nitride, or aluminum oxide. Dielectric film 9 has a larger thickness than silicon oxide film 8. The thickness of the dielectric film is not less than the wavelength λ of the SH (shear horizontal) waves, which are the main acoustic waves. As a result, the main acoustic waves can be confined in acoustic wave device 5. The thickness of dielectric film 9 is preferably not more than 5λ, hence providing acoustic wave device 5 with a low profile/Acoustic wave device 5 of the embodiment will be detailed below.

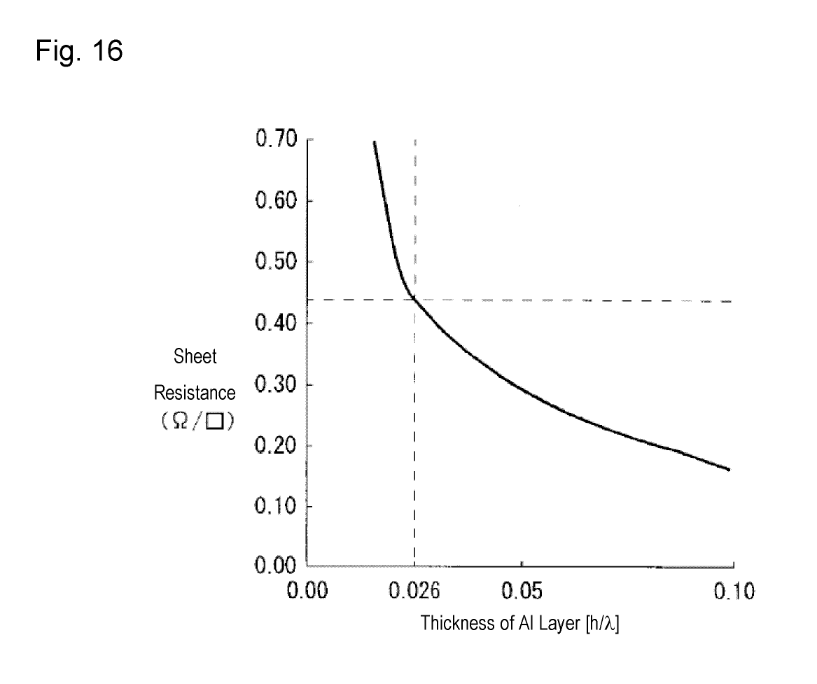

FIG. 16 shows the relation between the sheet resistance (Ω/□) of the entire IDT electrode 7 and the thickness (λ) of second electrode layer 11 in the case that first electrode layer 10 is made of a W layer with a thickness of 0.04λ and an Al layer as second electrode layer 11 formed on the W layer. As shown in FIG. 16, in the case that the thickness of second electrode layer 11 is less than 0.026λ, the resistance of the entire IDT electrode 7 is higher than 0.44Ω/□ with an inflection point. Thus, the resistance of IDT electrodes 7 can be reduced by setting the thickness of second electrode layer 11 to be not less than 0.026λ, thereby reducing the insertion loss of acoustic wave device 5.

In the case that the thickness of second electrode layer 11 is not less than 0.026λ, the resistance of IDT electrodes 7 does not depend on the thickness of first electrode layer 10. This is because, in the case that the thickness of second electrode layer 11 made of Al is not less than 0.026λ, most of a current flowing through IDT electrode 7 flows through second electrode layer 11.

As described above, in acoustic wave device 5, the unevenness in thickness of silicon oxide film 8 can be reduced by setting the total thickness of each IDT electrode 7 to be not more than 0.15λ. The thickness of first electrode layer 10 mainly made of W not less than 0.03λ can improve the power resistance characteristics of the acoustic wave device. The thickness of second electrode layer 11 mainly made of Al not less than 0.026λ can reduce the resistance of IDT electrodes 7. As a result, the insertion loss of acoustic wave device 5 can be reduced.

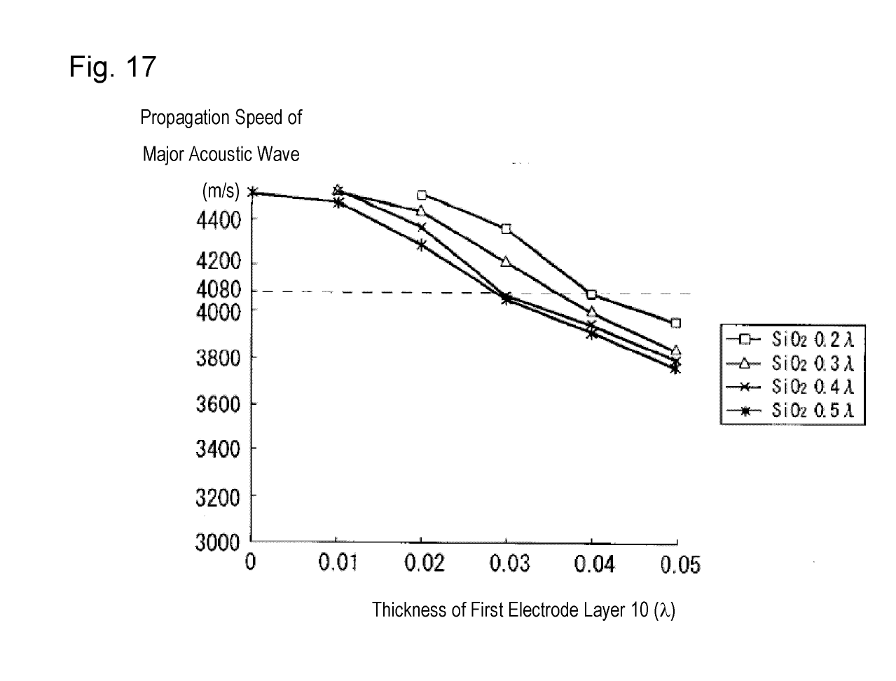

FIG. 17 shows the relation between the thickness (λ) of the first electrode layer and the propagation speed (m/s) of the main acoustic waves that propagate through IDT electrodes 7 in the case that piezoelectric body 6 is a 25 degree rotated Y-cut X-propagation lithium niobate substrate; dielectric film 9 is made of silicon nitride (SiN) with a thickness of 1λ; and the thickness D of silicon oxide film 8 is changed in the range from 0.2λ to 0.5λ. It is assumed that the silicon oxide film has a flat upper surface. It is assumed that second electrode layer 11 has a thickness of 0.026λ. As the thickness of second electrode layer 11 becomes larger than this, the propagation speed of the main acoustic waves becomes slightly smaller. If the thickness of dielectric film 9 is not less than 1λ, the thickness of dielectric film 9 does not affect the propagation speed (m/s) of the main acoustic waves that propagate through IDT electrode 7. The propagation speed of the main acoustic waves shown in FIG. 17 is the propagation speed at the antiresonant frequency of the main acoustic waves. This is applied to the other figures showing the propagation speed of the main acoustic waves. When we focus on the energy loss of the main acoustic waves, it may be considered to be important to focus on the energy loss at both the resonant and antiresonant frequencies of the main acoustic waves. However, the propagation speed of the main acoustic waves is higher at the antiresonant frequency than at the resonant frequency. For this reason, the antiresonant frequency can be used to compare the propagation speed between the main acoustic waves and bulk waves in terms of the energy loss.

As shown in FIG. 17, in the case that the thickness of silicon oxide film 8 is 0.2λ, the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.04λ. This can reduce the energy loss of the main acoustic waves due to bulk wave radiation.

In the case that the thickness of silicon oxide film 8 is 0.3λ, the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.037λ. This can reduce the energy loss of the main acoustic waves due to bulk wave radiation.

In the case that the thickness of silicon oxide film 8 is 0.4λ, the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.03λ. This can reduce the energy loss of the main acoustic waves due to bulk wave radiation.

In the case that the thickness of silicon oxide film 8 is 0.5λ the propagation speed of the main acoustic waves that propagate through IDT electrodes 7 is lower than the propagation speed (4080 m/s) of the slowest the transverse wave (bulk wave) that propagate through piezoelectric body 6 if the thickness of first electrode layer 10 is not less than 0.03λ. This can reduce the energy loss of the main acoustic waves due to bulk wave radiation.

Thus, the propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.04λ in the case that the thickness of silicon oxide film 8 is not less than 0.2λ and is less than 0.3λ; the thickness of first electrode layer 10 is not less than 0.037λ in the case that the thickness of silicon oxide film 8 is not less than 0.3λ and is less than 0.4λ; and the thickness of first electrode layer 10 is not less than 0.03λ in the case that the thickness of silicon oxide film 8 ranges from 0.4λ to 0.5λ.

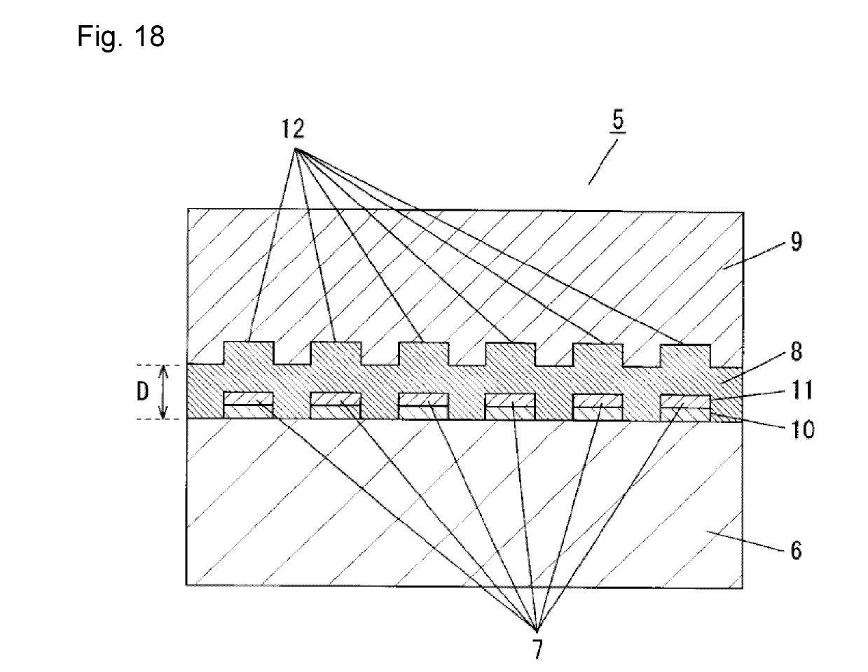

FIG. 18 is a schematic sectional view of another acoustic wave device according to Embodiment 3 (a schematic sectional view perpendicular to a direction in which electrode fingers of the IDT electrode extend). The device shown in FIG. 18 is different from the device shown in FIG. 15 in that projections 12 are provided on the upper surface of silicon oxide film 8 above the electrode fingers of IDT electrode 7.

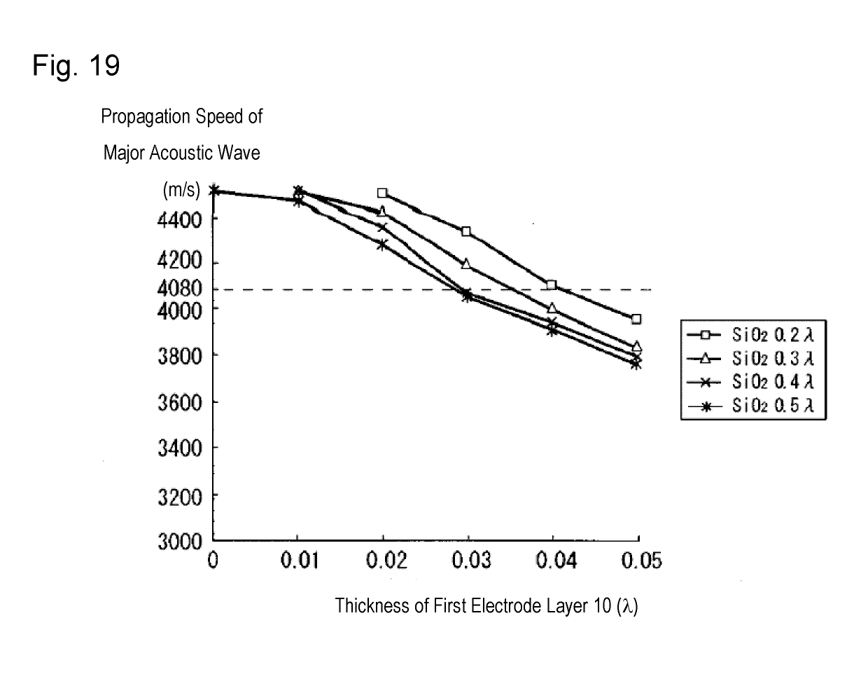

FIG. 19 shows the relation between the thickness (λ) of the first electrode layer and the propagation speed (m/s) of the main acoustic waves that propagate through IDT electrodes 7 in the case that the cross section of projections 12 have the same shape as that of the electrode fingers of IDT electrode 7; piezoelectric body 6 is a 25 degree rotated Y-cut X-propagation lithium niobate substrate; dielectric film 9 is made of silicon nitride (SiN) with a thickness of 1λ; and the thickness D of silicon oxide film 8 is changed in the range from 0.2λ to 0.5λ. It is assumed that second electrode layer 11 has a thickness of 0.026λ. As the thickness of second electrode layer 11 becomes larger than this, the propagation speed of the main acoustic waves becomes slightly smaller. If the thickness of dielectric film 9 is not less than 1λ, the thickness of dielectric film 9 does not affect the propagation speed (m/s) of the main acoustic waves that propagate through IDT electrode 7.

As shown in FIG. 19, in the case that the thickness of silicon oxide film 8 is 0.2λ the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.04λ. This can reduce the energy loss of the main acoustic waves due to bulk wave radiation.

In the case that the thickness of silicon oxide film 8 is 0.3λ, the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.035λ. This can reduce the energy loss of the main acoustic waves due to bulk wave radiation.

In the case that the thickness of silicon oxide film 8 is 0.4λ, the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.029λ. This can reduce the energy loss of the main acoustic waves due to bulk wave radiation.

In the case that the thickness of silicon oxide film 8 is 0.5λ, the propagation speed of the main acoustic waves that propagate through IDT electrodes 7 is lower than the propagation speed (4080 m/s) of the slow transverse wave (bulk wave) that propagates through piezoelectric body 6 if the thickness of first electrode layer 10 is not less than 0.028λ. This can reduce the energy loss of the main acoustic waves due to bulk wave radiation.

Projections 12 thus provided on the upper surface of silicon oxide film 8 above the fingers of IDT electrodes 7 slightly reduce the propagation speed of the main acoustic waves that propagate through IDT electrodes 7. Thus, even if first electrode layer 10 has a small thickness, the energy loss of the main acoustic waves due to bulk wave radiation is lower than the device having no projection 12.

Thus, projections 12 on the upper surface of silicon oxide film 8 above the fingers of IDT electrodes 7 can reduce the energy loss of the main acoustic waves due to bulk wave radiation under the following conditions. The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.04λ in the case that the thickness of silicon oxide film 8 is not less than 0.2λ and is less than 0.3λ; the thickness of first electrode layer 10 is not less than 0.035λ in the case that the thickness of silicon oxide film 8 is not less than 0.3λ and is less than 0.4λ; the thickness of first electrode layer 10 is not less than 0.029λ in the case that the thickness of silicon oxide film 8 is not less than 0.4λ and is less than 0.5λ; and the thickness of first electrode layer 10 is not less than 0.028λ in the case that the thickness of silicon oxide film 8 is 0.5λ.

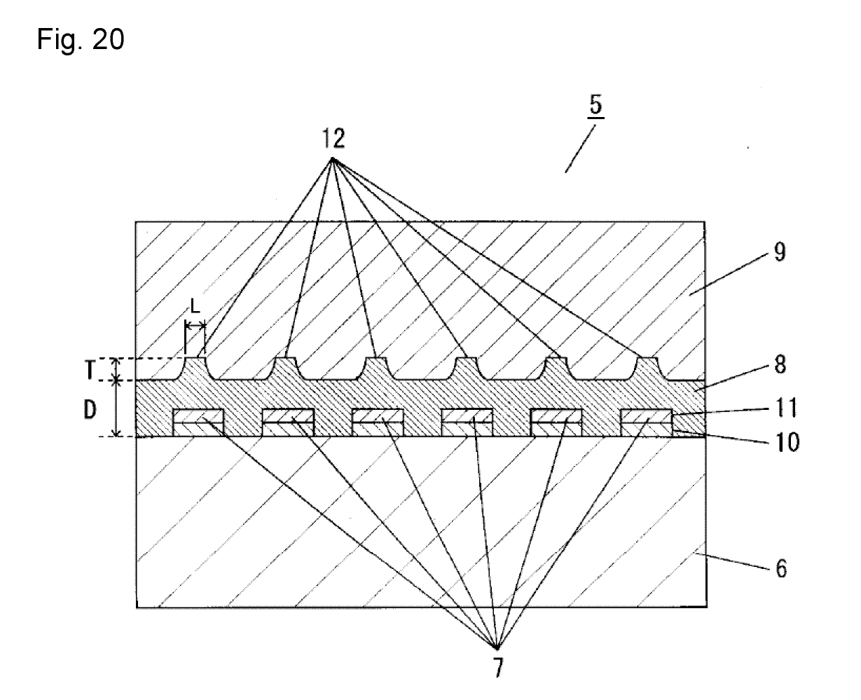

As shown in FIG. 20, in the case that the cross section of projections 12 are smaller than that of the fingers of IDT electrodes 7, the propagation speed of the main acoustic waves propagating through first electrode layer 10 has a value between the values shown in FIGS. 17 and 19.

Projections 12 will be detailed below.

Projections 12 of silicon oxide film 8 are preferably curved concavely from the top to the bottom. The width L of the top portion of projection 12 is defined as the distance between two points where either the concave curves or extension lines thereof intersects with a straight line which is parallel to the upper surface of piezoelectric body 6 and which passes the top of the projection. In this case, the width L of the top portion is smaller than the width of the fingers of IDT electrodes 7. This structure allows a mass added to silicon oxide film 8 at projections 12 to change continuously and gradually and prevents unwanted reflections due to the shape of silicon oxide film 8, thereby improving the electrical characteristics of acoustic wave device 5.

The width of the top portions of projections 12 is preferably one half or less of the width of the fingers of IDT electrode 7. The center positions of the top portions of projections 12 are preferably substantially directly above the center positions of the electrode fingers. This further improves the reflectance at the electrode fingers due to the mass addition effect, thereby improving the electrical characteristics of acoustic wave device 5.

The height T of projections 12 and the total thickness h of IDT electrode 7 may preferably satisfy 0.03λ<T≦h. According to a study of the relation between the height T from the bottom portion to the top portion of projections 12 of silicon oxide film 8 and the electrical characteristics, the reflectance is very high in the case that the height T is higher than 0.03λ, and silicon oxide film 8 has a flat surface. If the height T is larger than the thickness h of IDT electrodes 7, an additional process is required to produce silicon oxide film 8, thereby complicating the production method.

Second electrode layer 11 preferably contacts a part of side surfaces of first electrode layer 10. This arrangement prevents silicon oxide film 8 from peeling off from piezoelectric body 6.

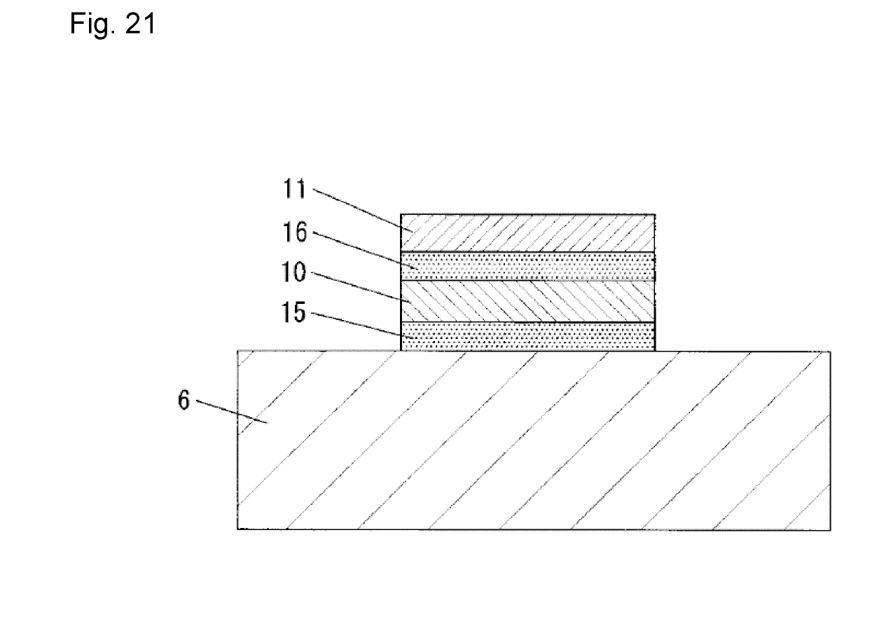

As shown in FIG. 21, adhesive layer 15 composed of a Ti layer, a TiN layer, a Cr layer, or a NiCr layer between piezoelectric body 6 and first electrode layer 10 can prevent IDT electrode 7 from peeling off from piezoelectric body 6.

An adhesive layer 16 composed of a Ti layer, a TiN layer, a Cr layer, or a NiCr layer between first electrode layer 10 and second electrode layer 11 as shown in FIG. 21 can improve the power resistance characteristics of acoustic wave device 5.

### Exemplary Embodiment 4

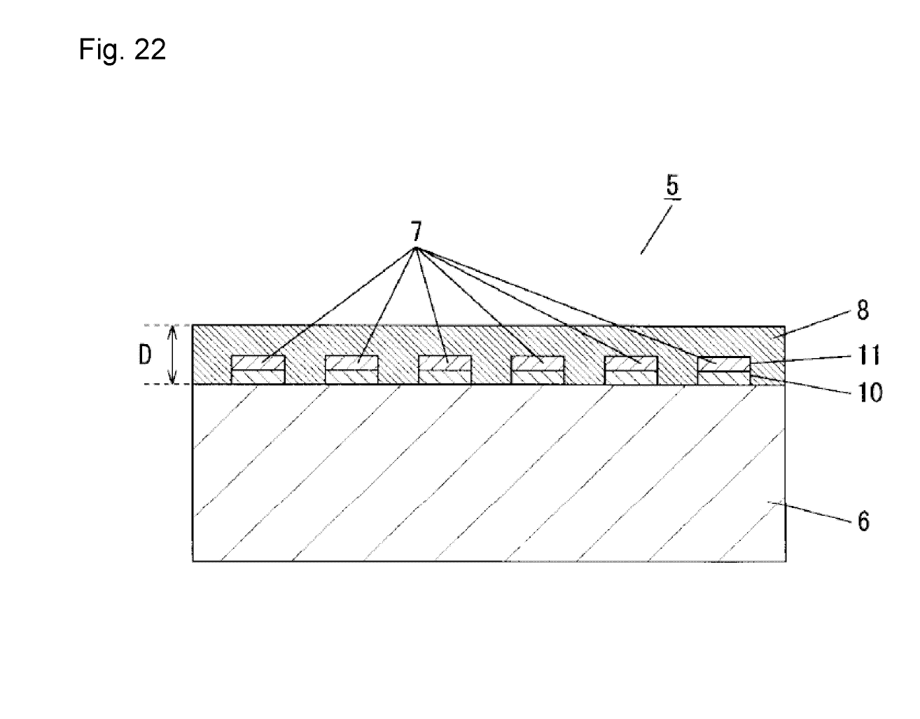

Exemplary Embodiment 4 of the present invention will be described with reference to drawings. FIG. 22 is a schematic sectional view of an acoustic wave device according to Exemplary Embodiment 4 (a schematic sectional view perpendicular to a direction in which electrode fingers of an IDT electrode extend). Components identical to those of Embodiment 3 are denoted by the same reference numerals, and thus a description thereof will be omitted.

The device according to Embodiment 4 is different from the device according to Embodiment 2 in that first electrode layer 10 is mainly made of W (tungsten).

In FIG. 22, acoustic wave device 5 does not include dielectric film 9 according to Embodiment 3, and is a surface wave device for exciting the main acoustic waves by distributing energy either to the surface of piezoelectric body 6 or to silicon oxide film 8.

IDT electrode 7 has a total thickness not more than 0.15λ. First electrode layer 10 has a thickness not less than 0.04λ. Second electrode layer 11 has a thickness not less than 0.026λ.

The thickness of silicon oxide film 8 is determined such that the frequency temperature characteristics of the main acoustic waves excited by IDT electrodes 7 can be not more than a predetermined value (10 ppm/° C.).

In the case that the thickness of silicon oxide film 8 ranges from 0.1λ to 0.5λ, the above-mentioned levels can be satisfied, thereby achieving both prevention of leakage of the main acoustic waves and improvement of the frequency temperature characteristics.

Similar to Embodiment 3, when the thickness of second electrode layer 11 is less than 0.026λ, the resistance of the entire IDT electrode 7 is high. Thus, the resistance of IDT electrodes 7 can be reduced by setting the thickness of second electrode layer 11 to be not less than 0.026λ, thereby reducing the insertion loss of acoustic wave device 5.

As described above, in acoustic wave device 5, the unevenness in thickness of silicon oxide film 8 can be reduced by setting the total thickness of each IDT electrode 7 to be not more than 0.15λ. The thickness of first electrode layer 10 mainly made of W not less than 0.004λ can improve the power resistance characteristics of acoustic wave device 5. The thickness of second electrode layer 11 mainly made of Al not less than 0.026λ can reduce the resistance of IDT electrodes 7. As a result, the insertion loss of acoustic wave device 5 can be reduced.

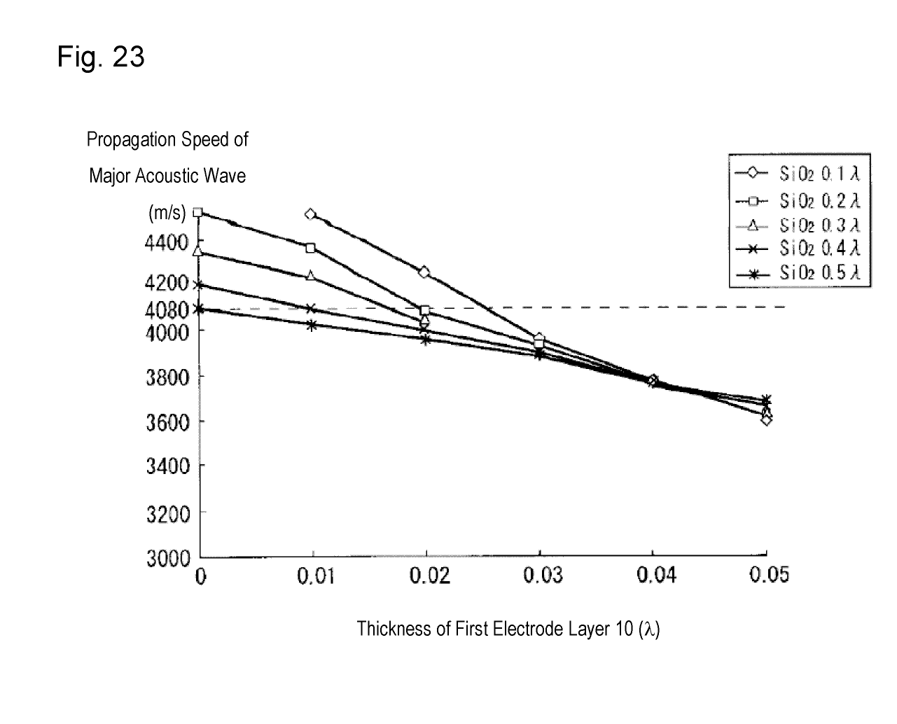

FIG. 23 shows the relation between the thickness (λ) of the first electrode layer and the propagation speed (m/s) of the main acoustic waves that propagate through IDT electrodes 7 in the case that: piezoelectric body 6 is a 25 degree rotated Y-cut X-propagation lithium niobate substrate; and the thickness D of silicon oxide film 8 is changed in the range from 0.1λ to 0.5λ. It is assumed that the silicon oxide film has a flat upper surface. Second electrode layer 11 has a thickness of 0.026λ. As the thickness of second electrode layer 11 becomes larger than this, the propagation speed of the main acoustic waves becomes slightly smaller.

As shown in FIG. 23, in the case that the thickness of silicon oxide film 8 is 0.1λ, if the thickness of first electrode layer 10 is not less than 0.027λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.2λ, if the thickness of first electrode layer 10 is not less than 0.02λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3, if the thickness of first electrode layer 10 is not less than 0.018λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.4λ, if the thickness of first electrode layer 10 is not less than 0.01λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.5λ, if the thickness of first electrode layer 10 is not less than 0.004λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.027λ in the case that the thickness of silicon oxide film 8 is not less than 0.1λ and is less than 0.2λ; the thickness of first electrode layer 10 is not less than 0.02λ in the case that the thickness of silicon oxide film 8 is not less than 0.2λ and is less than 0.3λ; the thickness of first electrode layer 10 is not less than 0.018λ in the case that the thickness of silicon oxide film 8 is not less than 0.3λ and is less than 0.4λ; the thickness of first electrode layer 10 is not less than 0.01λ in the case that the thickness of silicon oxide film 8 not less than is 0.4λ and is less than 0.5λ; and the thickness of first electrode layer 10 is not less than 0.004λ in the case that the thickness of silicon oxide film 8 is 0.5λ.

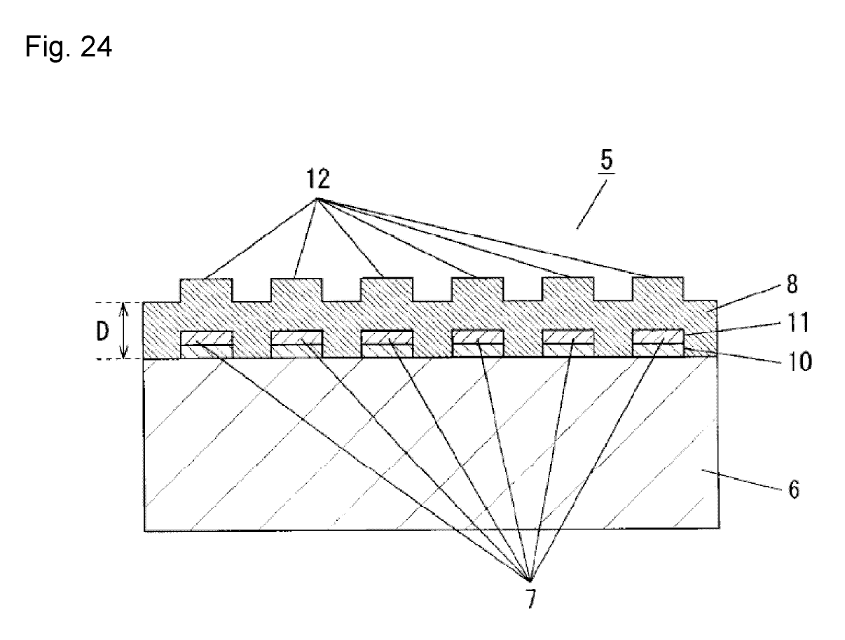

FIG. 24 is a schematic sectional view of another acoustic wave device according to Embodiment 4 (a schematic sectional view perpendicular to a direction in which electrode fingers of the IDT electrode extend). The device shown in FIG. 24 is different from the device shown in FIG. 22 in that projections 12 are provided on the upper surface of silicon oxide film 8 above the fingers of IDT electrode 7.

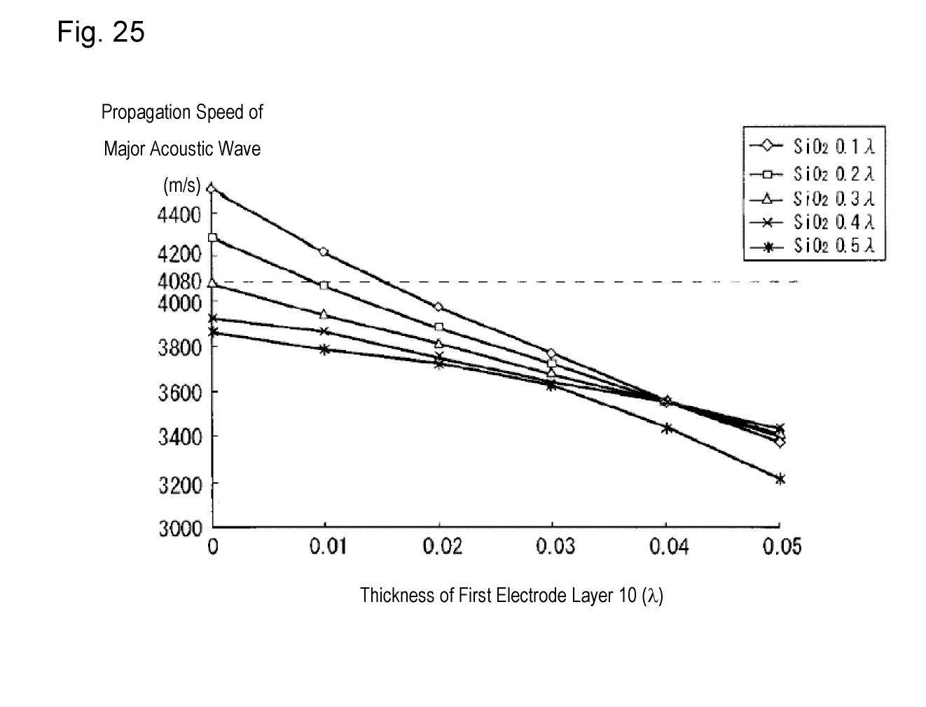

FIG. 25 shows the relation between the thickness (λ) of first electrode layer 10 and the propagation speed (m/s) of the main acoustic waves that propagate through IDT electrodes 7 in the case that the cross section of projections 12 have the same shape as that of the electrode fingers of IDT electrode 7; piezoelectric body 6 is a 25 degree rotated Y-cut X-propagation lithium niobate substrate; and the thickness D of silicon oxide film 8 is changed in the range from 0.1λ to 0.5λ. It is assumed that second electrode layer 11 has a thickness of 0.026λ. As the thickness of second electrode layer 11 becomes larger than this, the propagation speed of the main acoustic waves becomes slightly smaller.

As shown in FIG. 25, in the case that the thickness of silicon oxide film 8 is 0.1λ, if the thickness of first electrode layer 10 is not less than 0.016λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.2λ, if the thickness of first electrode layer 10 is not less than 0.009λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, 0.4λ, or 0.5λ, even if first electrode layer 10 is not provided, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

Projections 12 thus provided on the upper surface of silicon oxide film 8 above the fingers of IDT electrodes 7 slightly reduce the propagation speed of the main acoustic waves that propagate through IDT electrodes 7. Thus, even if first electrode layer 10 has a small thickness, the energy loss of the main acoustic waves due to bulk wave radiation is lower than the device including no projection 12.

Thus, projections 12 on the upper surface of silicon oxide film 8 above the fingers of IDT electrodes 7 can reduce the energy loss of the main acoustic waves due to bulk wave radiation under the following conditions. The propagation speed of the main acoustic waves that propagate through IDT electrodes 7 is lower than the propagation speed (4080 m/s) of the slowest one of the transverse waves (bulk waves) that propagate through piezoelectric body 6, thereby reducing the energy loss of the main acoustic waves due to bulk wave radiation in the following conditions: the thickness of first electrode layer 10 is not less than 0.016λ in the case that the thickness of silicon oxide film 8 is not less than 0.1λ and is less than 0.2λ; and the thickness of first electrode layer 10 is not less than 0.009λ in the case that the thickness of silicon oxide film 8 is not less than 0.3λ and is less than 0.3λ.

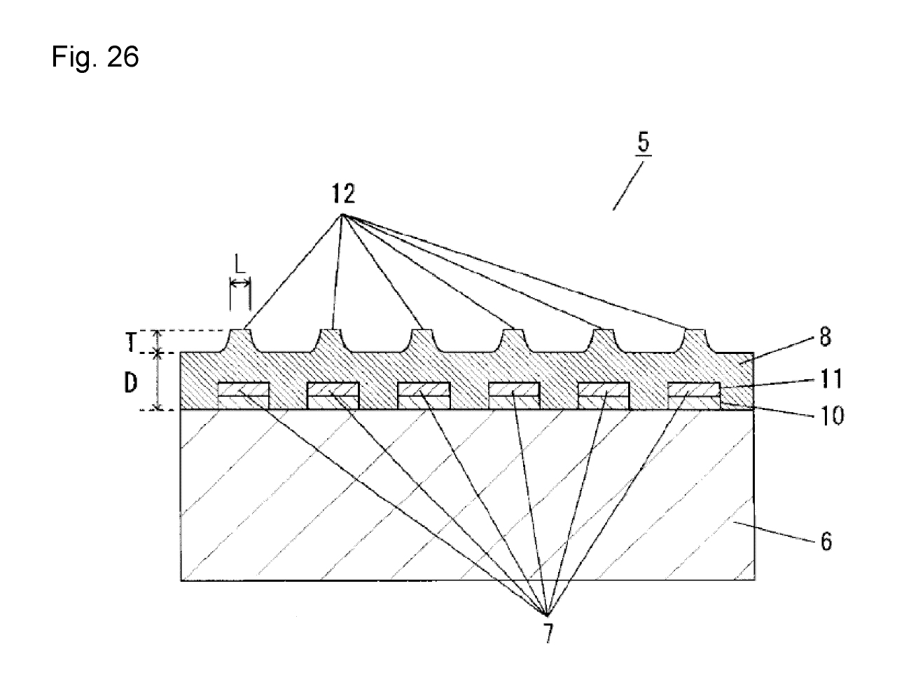

As shown in FIG. 26, in the case that the cross section of projections 12 are smaller than that of the electrode fingers of IDT electrode 7, the propagation speed of the main acoustic waves propagating through first electrode layer 10 has a value between the values shown in FIGS. 23 and 25.

Projections 12 will be detailed below.

Projections 12 of silicon oxide film 8 are preferably curved concavely from the top to the bottom. The width L of the top portion of projection 12 is defined as the distance between two points where either the concave curves or extension lines thereof intersects with a straight line which is parallel to the upper surface of piezoelectric body 6 and which passes the top of the projection. In this case, the width L of the top portion is smaller than the width of the fingers of IDT electrodes 7. This structure allows a mass added to silicon oxide film 8 at projections 12 to change continuously and gradually and prevents unwanted reflections due to the shape of silicon oxide film 8, thereby improving the electrical characteristics of acoustic wave device 5.

The width of the top portions of projections 12 is preferably one half or less of the width of the fingers of IDT electrode 7. The center positions of the top portions of projections 12 are preferably substantially directly above the center positions of the electrode fingers. This further improves the reflectance at the electrode fingers due to the mass addition effect, thereby improving the electrical characteristics of acoustic wave device 5.

The height T of projections 12 and the total thickness h of IDT electrode 7 may preferably satisfy 0.03λ<T≦h. According to a study of the relation between the height T from the bottom portion to the top portion of projections 12 of silicon oxide film 8 and the electrical characteristics, the reflectance is very high in the case that the height T is higher than 0.03λ, and silicon oxide film 8 has a flat surface. If the height T is larger than the thickness h of IDT electrodes 7, an additional process is required to produce silicon oxide film 8, thereby complicating the production method. The method of producing acoustic wave device 5 according to Embodiment 4 is identical to that of Embodiment 2.

It is understood that adhesive layers 15 and 16 according to Embodiment 3 can be applied to the IDT electrode according to Embodiment 4.

### Exemplary Embodiment 5

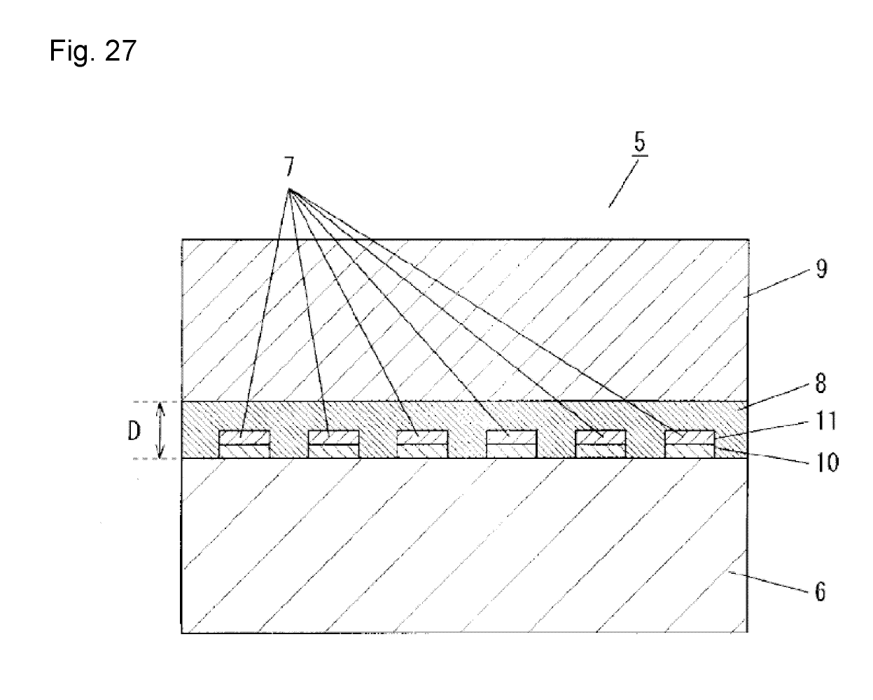

Exemplary Embodiment 5 of the present invention will be described with reference to drawings. FIG. 27 is a schematic sectional view of an acoustic wave device according to Exemplary Embodiment 5 (a schematic sectional view perpendicular to a direction in which electrode fingers of an IDT electrode extend).

The device according to Embodiment 5 is different from the device according to Embodiment 1 in that first electrode layer 10 is mainly made of Pt (platinum).

In FIG. 27, acoustic wave device 5 includes piezoelectric body 6 IDT electrode 7 disposed on piezoelectric body 6 to excite main acoustic waves (such as shear horizontal waves) having a wavelength λ; and silicon oxide film 8 disposed on piezoelectric body 6 to cover IDT electrode 7. Silicon oxide film 8 has thickness ranging from 0.20λ to 0.50λ. Acoustic wave device 5 further includes dielectric film 9 disposed on silicon oxide film 8. Dielectric film 9 allows transverse waves to propagate through the dielectric film faster than transverse waves propagating through silicon oxide film 8. Acoustic wave device 5 is a boundary wave device which excites main acoustic waves while confining most of the energy in the boundary between piezoelectric body 6 and silicon oxide film 8.

Piezoelectric body 6 is made of a lithium niobate (LiNbO₃) substrate, but may alternatively be made of other piezoelectric single crystal medium, such as a crystal substrate or thin film thereof, a lithium tantalite (LiTaO₃) substrate or thin film thereof, or a potassium niobate (KNbO₃) substrate or thin film thereof.

In the case that piezoelectric body 6 is made of a lithium niobate substrate, the substrate preferably has an Euler angle (φ, θ, ψ) where −100°≦θ≦−60° to suppress spurious modes. As described in Japanese Patent Application No. 2009-251696, the Euler angle (φ, θ, ψ) of piezoelectric body 6 made of lithium niobate preferably satisfies the following ranges: −100°≦θ≦−60°; 1.193φ−2°≦ψ≦1.194φ+2°; ψ≦−2φ−3°; and −2φ+3°≦ψ where φ and θ are the cut angles of piezoelectric body 6, and ψ is the propagation angle of the main acoustic waves in IDT electrode 7 on piezoelectric body 6. The Euler angle in these ranges can suppress the spurious modes in the vicinity of the frequency band where fast transverse waves are generated, while suppressing spurious modes caused by a Rayleigh wave.

IDT electrode 7 is an interdigital transducer electrode having a comb-shape in view from above acoustic wave device 5. IDT electrode 7 includes first electrode layer 10 mainly made of Pt (platinum) and second electrode layer 11 mainly made of Al (aluminum). First electrode layer 10 is disposed on piezoelectric body 6, and second electrode layer 11 is disposed on first electrode layer 10. First electrode layer 10 may contain, for example, Si, and second electrode layer 11 may contain, for example, Mg, Cu, or Si. This can improve the power resistance characteristics of IDT electrode 7.

IDT electrode 7 has a total thickness not more than 0.15λ. First electrode layer 10 has a thickness not less than 0.025λ. Second electrode layer 11 has a thickness not less than 0.026λ.

Silicon oxide film 8 is made of a medium having frequency temperature characteristics reverse to those of piezoelectric body 6, hence improving frequency temperature characteristics of acoustic wave device 5. The thickness of silicon oxide film 8 is determined such that the main acoustic waves have a lower velocity than the slowest transverse wave that propagate through piezoelectric body 6. This reduces leakage of the main acoustic waves toward piezoelectric body 6.

The thickness of silicon oxide film 8 is determined such that the frequency temperature characteristics of the main acoustic waves excited by IDT electrode 7 can be not more than a predetermined value (30 ppm/° C.). In the case that the thickness of silicon oxide film 8 ranges from 0.2λ to 0.5λ, the above-mentioned levels can be satisfied, thereby achieving both prevention of leakage of the main acoustic waves and improvement of the frequency temperature characteristics.

The thickness of silicon oxide film 8 used in this case indicates a distance D from the boundary between piezoelectric body 6 and silicon oxide film 8 to the upper surface of silicon oxide film 8 in the region where IDT electrodes 7 are not disposed and piezoelectric body 6 contacts silicon oxide film 8.

Dielectric film 9 is a medium which allows transverse waves to propagate through the dielectric film faster than the transverse waves propagating through silicon oxide film 8. Dielectric film 9 can be made of, for example, diamond, silicon, silicon nitride, aluminum nitride, or aluminum oxide. Dielectric film 9 has a larger thickness than silicon oxide film 8. The thickness of dielectric film 9 I not less than the wavelength λ of the SH (shear horizontal) waves, which are the main acoustic waves. As a result, the main acoustic waves can be confined in acoustic wave device 5. The thickness of dielectric film 9 is preferably not more than 5λ to provide acoustic wave device 5 with a low profile.

Acoustic wave device 5 of this embodiment will be detailed below.

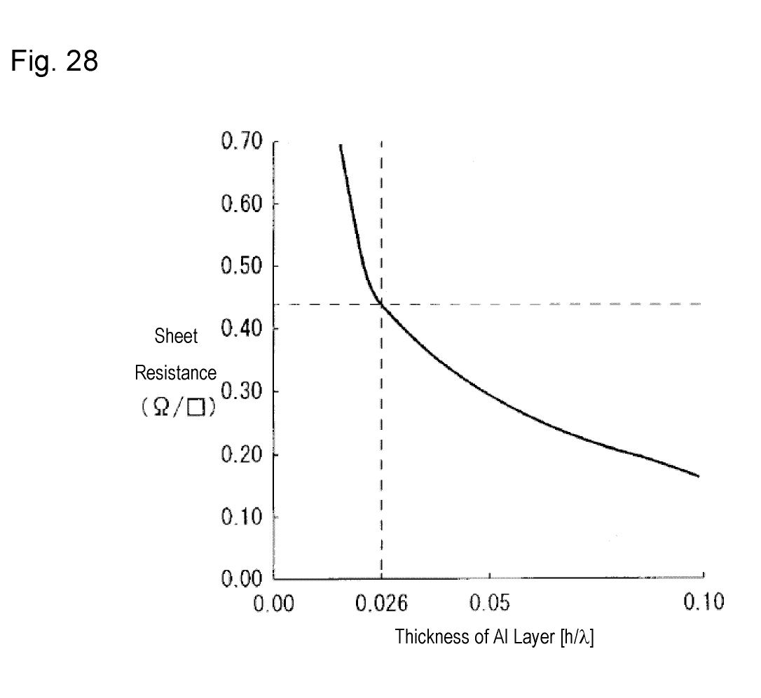

FIG. 28 shows the relation between the sheet resistance (Ω/□) of the entire IDT electrode 7 and the thickness (φ) of second electrode layer 11 in the case that first electrode layer 10 is made of a Pt layer with a thickness of 0.03λ and an Al layer as second electrode layer 11 is formed on the Pt layer. As shown in FIG. 28, if the thickness of second electrode layer 11 is less than 0.026λ, the resistance of the entire portion of each IDT electrode 7 is higher than 0.44Ω/□ with an inflection point. Thus, the resistance of IDT electrodes 7 can be reduced by setting the thickness of second electrode layer 11 to be not less than 0.026λ, thereby reducing the insertion loss of acoustic wave device 5.

If the thickness of second electrode layer 11 is not less than 0.026λ, the resistance of IDT electrodes 7 does not depend on the thickness of first electrode layer 10. This is because, in the case that the thickness of second electrode layer 11 made of Al is not less than 0.026λ, most of a current flowing through IDT electrodes 7 flows through second electrode layer 11.

As described above, in acoustic wave device 5, the unevenness in thickness of silicon oxide film 8 can be reduced by setting the total thickness of each IDT electrode 7 to be not more than 0.15λ. The thickness of first electrode layer 10 mainly made of Pt not less than 0.025λ can improve the power resistance characteristics of the acoustic wave device. The thickness of second electrode layer 11 mainly made of Al not less than 0.026λ can reduce the resistance of IDT electrodes 7. As a result, the insertion loss of acoustic wave device 5 can be reduced.

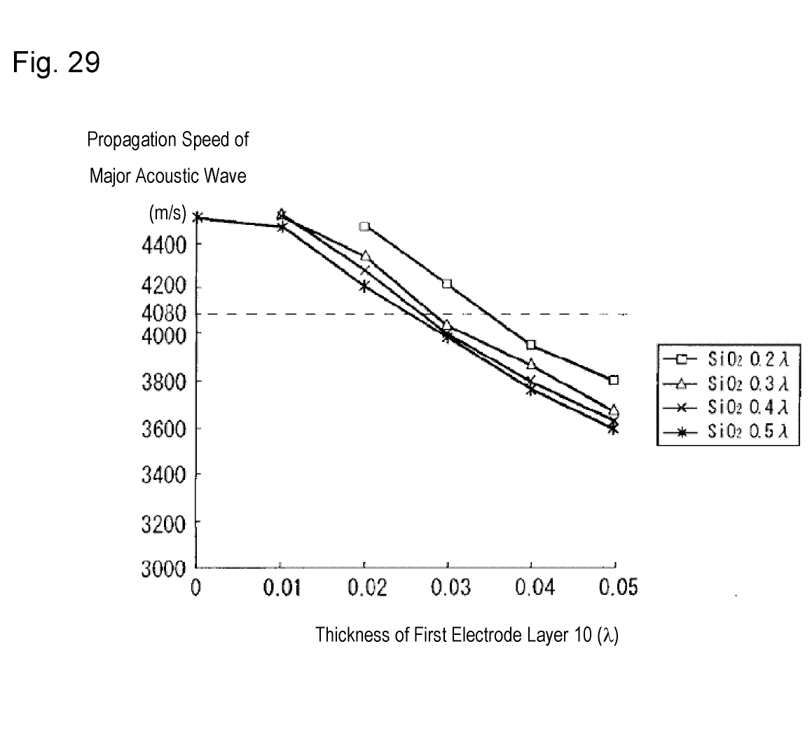

FIG. 29 shows the relation between the thickness (λ) of the first electrode layer and the propagation speed (m/s) of the main acoustic waves that propagate through IDT electrode 7 in the case that piezoelectric body 6 is a 25 degree rotated Y-cut X-propagation lithium niobate substrate; dielectric film 9 is made of silicon nitride (SiN) with a thickness of 1λ; and the thickness D of silicon oxide film 8 is changed in the range from 0.2λ to 0.5λ. It is assumed that the silicon oxide film has a flat upper surface. It is assumed that second electrode layer 11 has a thickness of 0.026λ. As the thickness of second electrode layer 11 becomes larger than this, the propagation speed of the main acoustic waves becomes slightly smaller. If the thickness of dielectric film 9 is not less than 1λ, the thickness of dielectric film 9 does not affect the propagation speed (m/s) of the main acoustic waves that propagate through IDT electrodes 7. The propagation speed of the main acoustic waves shown in FIG. 29 is the propagation speed at the antiresonant frequency of the main acoustic waves. This is applied to the other figures showing the propagation speed of the main acoustic waves. When we focus on the energy loss of the main acoustic waves, it may be considered to be important to focus on the energy loss at both the resonant and antiresonant frequencies of the main acoustic waves. However, the propagation speed of the main acoustic waves is higher at the antiresonant frequency than at the resonant frequency. For this reason, the antiresonant frequency can be used to compare the propagation speed between the main acoustic waves and bulk waves in terms of the energy loss.

As shown in FIG. 29, in the case that the thickness of silicon oxide film 8 is 0.2λ, if the thickness of first electrode layer 10 is not less than 0.035λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, if the thickness of first electrode layer 10 is not less than 0.029λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.4λ, if the thickness of first electrode layer 10 is not less than 0.027λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.5λ, if the thickness of first electrode layer 10 is not less than 0.025λ, the propagation speed of the main acoustic waves that propagate through IDT electrodes 7 is lower than the propagation speed (4080 m/s) of the slowest transverse wave (bulk wave) that propagate through piezoelectric body 6. This can reduce the energy loss of the main acoustic waves due to bulk wave radiation.

Thus, the propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.035λ in the case that the thickness of silicon oxide film 8 is not less than 0.2λ and is less than 0.3λ; the thickness of first electrode layer 10 is not less than 0.029λ in the case that the thickness of silicon oxide film 8 not less than 0.3λ and is less than 0.4λ; the thickness of first electrode layer 10 is not less than 0.027λ in the case that the thickness of silicon oxide film 8 is not less than 0.4λ and is less than 0.5λ; and the thickness of first electrode layer 10 is not less than 0.025λ in the case that the thickness of silicon oxide film 8 is 0.5λ.

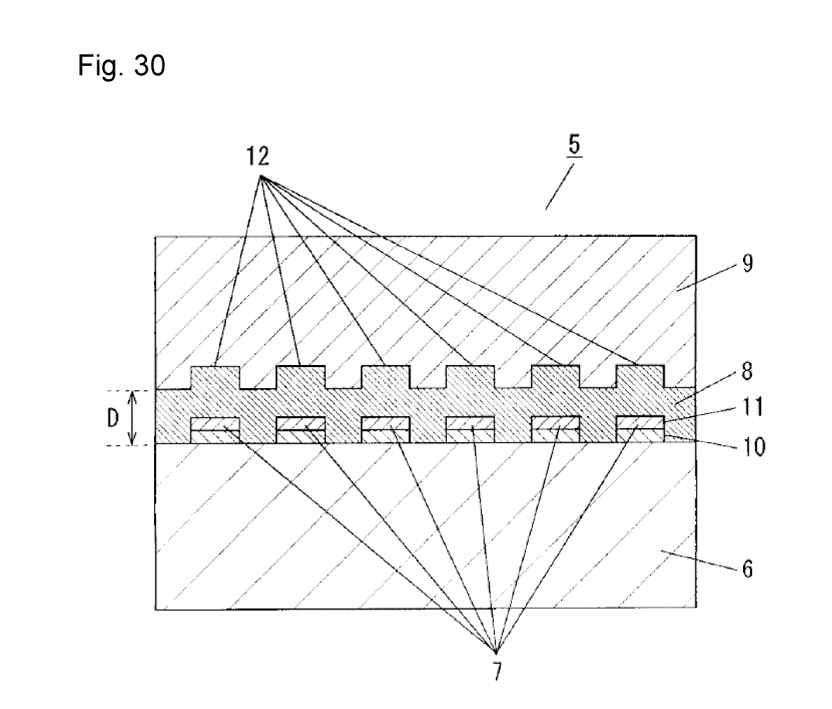

FIG. 30 is a schematic sectional view of another acoustic wave device according to Embodiment 5 (a schematic sectional view perpendicular to a direction in which electrode fingers of the IDT electrode extend). The device shown in FIG. 30 is different from the device shown in FIG. 27 in that projections 12 are provided on the upper surface of silicon oxide film 8 above the fingers of IDT electrode 7.

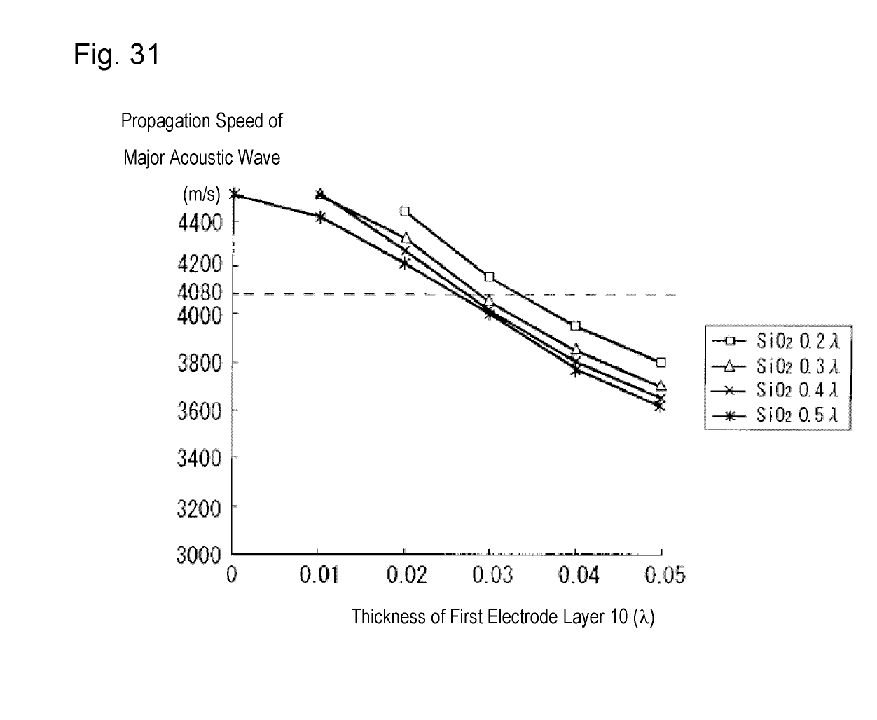

FIG. 31 shows the relation between the thickness (λ) of the first electrode layer and the propagation speed (m/s) of the main acoustic waves that propagate through IDT electrodes 7 in the case that the cross section of projections 12 have the same shape as that of the electrode fingers of IDT electrode 7; piezoelectric body 6 is made of a 25 degree rotated Y-cut X-propagation lithium niobate substrate; dielectric film 9 is made of silicon nitride (SiN) with a thickness of 1λ; and the thickness D of silicon oxide film 8 is changed in the range from 0.2λ to 0.5λ. It is assumed that second electrode layer 11 has a thickness of 0.026λ. As the thickness of second electrode layer 11 becomes larger than this, the propagation speed of the main acoustic waves becomes slightly smaller. If the thickness of dielectric film 9 is not less than 1λ, the thickness of dielectric film 9 does not affect the propagation speed (m/s) of the main acoustic waves that propagate through IDT electrode 7.

As shown in FIG. 31, in the case that the thickness of silicon oxide film 8 is 0.2λ, if the thickness of first electrode layer 10 is not less than 0.034λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, if the thickness of first electrode layer 10 is not less than 0.028λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.4λ, if the thickness of first electrode layer 10 is not less than 0.027λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.5λ, if the thickness of first electrode layer 10 is not less than 0.025λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

Projections 12 thus provided on the upper surface of silicon oxide film 8 above the fingers of IDT electrodes 7 slightly reduce the propagation speed of the main acoustic waves that propagate through IDT electrodes 7. Thus, even if first electrode layer 10 has a small thickness, the energy loss of the main acoustic waves due to bulk wave radiation is lower than in the device including no projection 12.

Thus, projections 12 on the upper surface of silicon oxide film 8 above the fingers of IDT electrodes 7 can reduce the energy loss of the main acoustic waves due to bulk wave radiation under the following conditions. The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.028λ in the case that the thickness of silicon oxide film 8 is not less than 0.2λ and is less than 0.3λ; the thickness of first electrode layer 10 is not less than 0.035λ in the case that the thickness of silicon oxide film 8 is not less than 0.3λ and is less than 0.4λ; the thickness of first electrode layer 10 is not less than 0.027λ in the case that the thickness of silicon oxide film 8 is not less than 0.4λ and is less than 0.5λ; and the thickness of first electrode layer 10 is not less than 0.025λ in the case that the thickness of silicon oxide film 8 is 0.5λ.

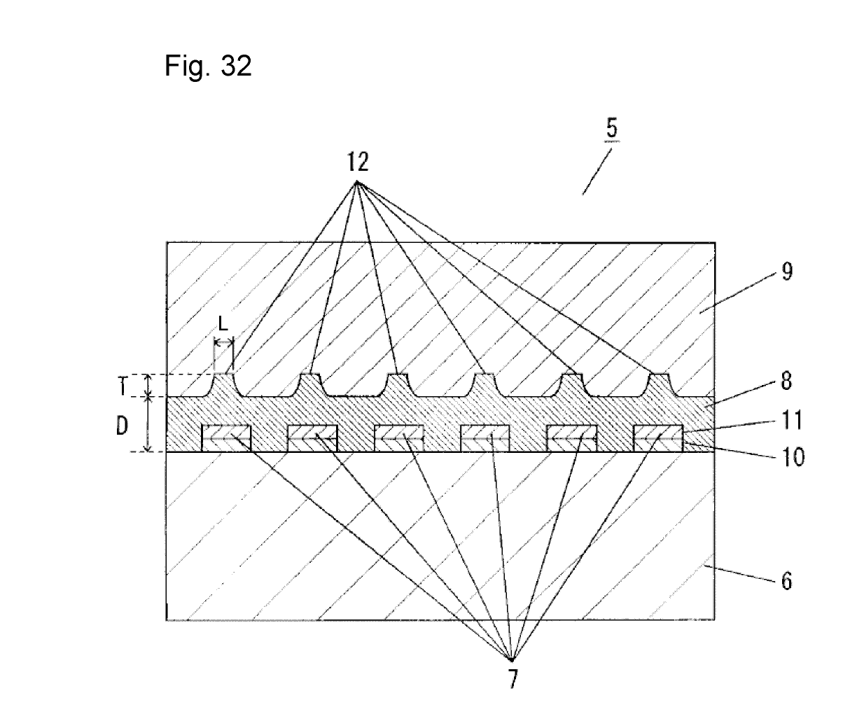

As shown in FIG. 32, in the case that projections 12 are smaller in cross section than the fingers of IDT electrodes 7, the propagation speed of the main acoustic waves propagating through first electrode layer 10 has a value between the values shown in FIGS. 29 and 31.

Projections 12 will be detailed below.

Projections 12 of silicon oxide film 8 are preferably curved concavely from the top to the bottom. The width L of the top portion of projection 12 is defined as the distance between two points where either the concave curves or extension lines thereof intersects with a straight line which is parallel to the upper surface of piezoelectric body 6 and which passes the top of the projection. In this case, the width L of the top portion is smaller than the width of the fingers of IDT electrodes 7. This structure allows a mass added to silicon oxide film 8 at projections 12 to change continuously and gradually and prevents unwanted reflections due to the shape of silicon oxide film 8, thereby improving the electrical characteristics of acoustic wave device 5.

The width of the top portions of projections 12 is preferably one half or less of the width of the fingers of IDT electrode 7. The center positions of the top portions of projections 12 are preferably substantially directly above the center positions of the electrode fingers. This further improves the reflectance at the electrode fingers due to the mass addition effect, thereby improving the electrical characteristics of acoustic wave device 5.

The height T of projections 12 and the total thickness h of IDT electrode 7 may preferably satisfy 0.03λ<T≦h. According to a study of the relation between the height T from the bottom portion to the top portion of projections 12 of silicon oxide film 8 and the electrical characteristics, the reflectance is very high in the case that the height T is higher than 0.03λ, and silicon oxide film 8 has a flat surface. If the height T is larger than the thickness h of IDT electrodes 7, an additional process is required to produce silicon oxide film 8, thereby complicating the production method.

Second electrode layer 11 preferably contacts a part of side surfaces of first electrode layer 10. This arrangement prevents silicon oxide film 8 from peeling off from piezoelectric body 6.

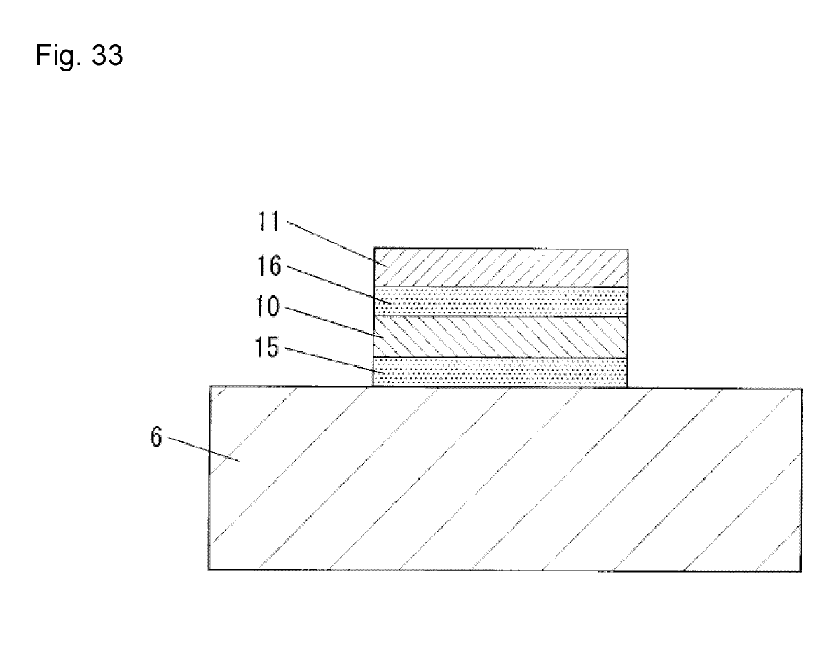

As shown in FIG. 33, adhesive layer 15 composed of a Ti layer, a TiN layer, a Cr layer, or a NiCr layer between piezoelectric body 6 and first electrode layer 10 can prevent IDT electrode 7 from peeling off from piezoelectric body 6.

An adhesive layer 16 composed of a Ti layer, a TiN layer, a Cr layer, or a NiCr layer between first electrode layer 10 and second electrode layer 11 as shown in FIG. 33 can improve the power resistance characteristics of acoustic wave device 5.

### Exemplary Embodiment 6

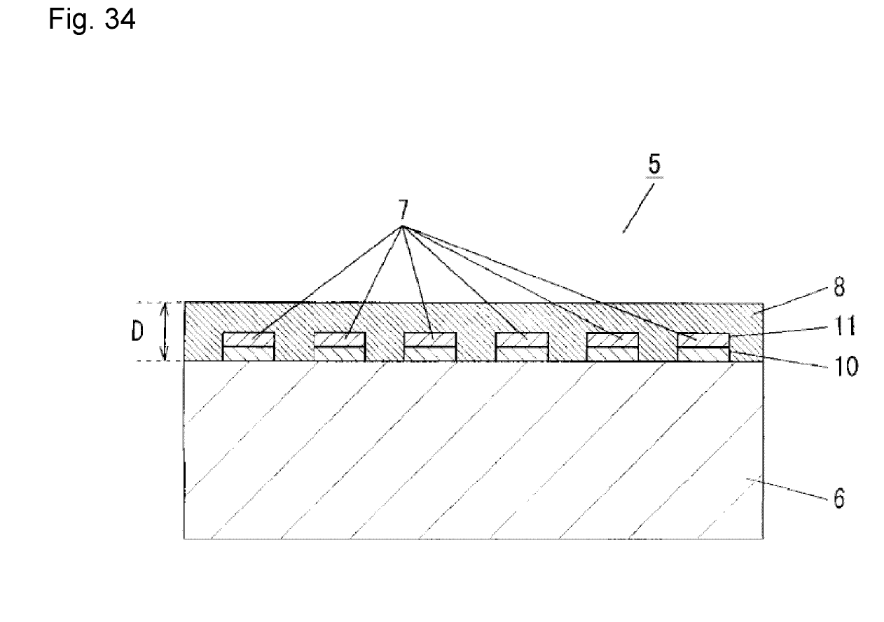

Exemplary Embodiment 6 of the present invention will be described with reference to drawings. FIG. 34 is a schematic sectional view of an acoustic wave device according to Exemplary Embodiment 6 (a schematic sectional view perpendicular to a direction in which electrode fingers of an IDT electrode extend). Components identical to those of Embodiment 5 are denoted by the same reference numerals, and their detailed description will be omitted.

The device according to Embodiment 6 is different from the device according to Embodiment 2 in that first electrode layer 10 is mainly made of Pt (platinum).

In FIG. 34, acoustic wave device 5 does not include dielectric film 9 according to Embodiment 5, and is a surface wave device exciting the main acoustic waves by distributing energy either to the surface of piezoelectric body 6 or to silicon oxide film 8.

IDT electrode 7 has a total thickness not more than 0.15λ. First electrode layer 10 has a thickness not less than 0.009λ. Second electrode layer 11 has a thickness not less than 0.026λ.

The thickness of silicon oxide film 8 is determined such that the frequency temperature characteristics of the main acoustic waves excited by IDT electrodes 7 can be not more than a predetermined value (10 ppm/°).

In the case that the thickness of silicon oxide film 8 ranges from 0.1λ to 0.5λ, the above-mentioned levels can be satisfied, thereby achieving both prevention of leakage of the main acoustic waves and improvement of the frequency temperature characteristics.

Similar to Embodiment 5, if the thickness of second electrode layer 11 is less than 0.026λ, the resistance of the entire IDT electrode 7 is high. Thus, the resistance of IDT electrode 7 can be reduced by setting the thickness of second electrode layer 11 to be not less than 0.026λ, thereby reducing the insertion loss of acoustic wave device 5.

As described above, in acoustic wave device 5, the unevenness in thickness of silicon oxide film 8 can be reduced by setting the total thickness of each IDT electrode 7 to be not more than 0.15λ. The thickness of first electrode layer 10 mainly made of Pt not less than 0.009λ can improve the power resistance characteristics of acoustic wave device 5. The thickness of second electrode layer 11 mainly made of Al not less than 0.026λ can reduce the resistance of IDT electrodes 7. As a result, the insertion loss of acoustic wave device 5 can be reduced.

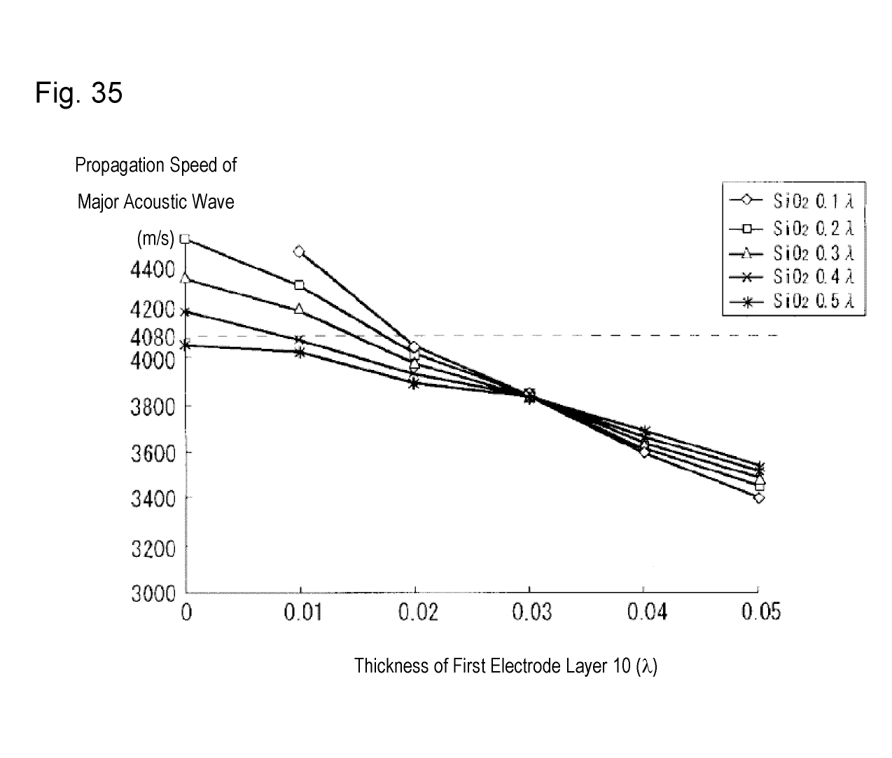

FIG. 35 shows the relation between the thickness (λ) of the first electrode layer and the propagation speed (m/s) of the main acoustic waves that propagate through IDT electrodes 7 in the case that piezoelectric body 6 is made of a 25 degree rotated Y-cut X-propagation lithium niobate substrate; and the thickness D of silicon oxide film 8 is changed in the range from 0.1λ to 0.5λ. It is assumed that the silicon oxide film has a flat upper surface, and second electrode layer 11 has a thickness of 0.026λ. As the thickness of second electrode layer 11 becomes larger than this, the propagation speed of the main acoustic waves becomes slightly smaller.

As shown in FIG. 35, in the case that the thickness of silicon oxide film 8 is 0.1λ, if the thickness of first electrode layer 10 is not less than 0.027λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.2λ, if the thickness of first electrode layer 10 is not less than 0.018λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3, if the thickness of first electrode layer 10 is not less than 0.016λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.4λ, if the thickness of first electrode layer 10 is not less than 0.009λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.5λ even if first electrode layer 10 is not provided, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.02λ in the case that the thickness of silicon oxide film 8 is not less than 0.1λ and is less than 0.2λ; the thickness of first electrode layer 10 is not less than 0.018λ in the case that the thickness of silicon oxide film 8 is not less than 0.2λ and is less than 0.3λ; the thickness of first electrode layer 10 is not less than 0.016λ in the case that the thickness of silicon oxide film 8 is not less than 0.3λ and is less than 0.4λ; and the thickness of first electrode layer 10 is not less than 0.009λ in the case that the thickness of silicon oxide film 8 is not less than 0.4λ and is less than 0.5λ.

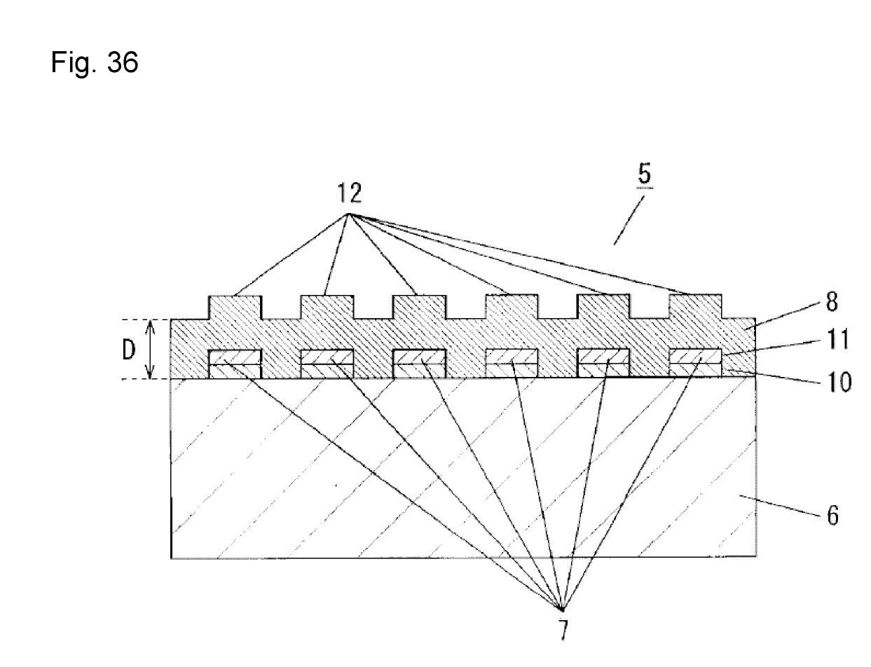

FIG. 36 is a schematic sectional view of another acoustic wave device according to Embodiment 6 (a schematic sectional view perpendicular to a direction in which the electrode fingers of the IDT electrode extend). The device shown in FIG. 36 is different from the device shown in FIG. 34 in that projections 12 are provided on the upper surface of silicon oxide film 8 above the fingers of IDT electrodes 7.

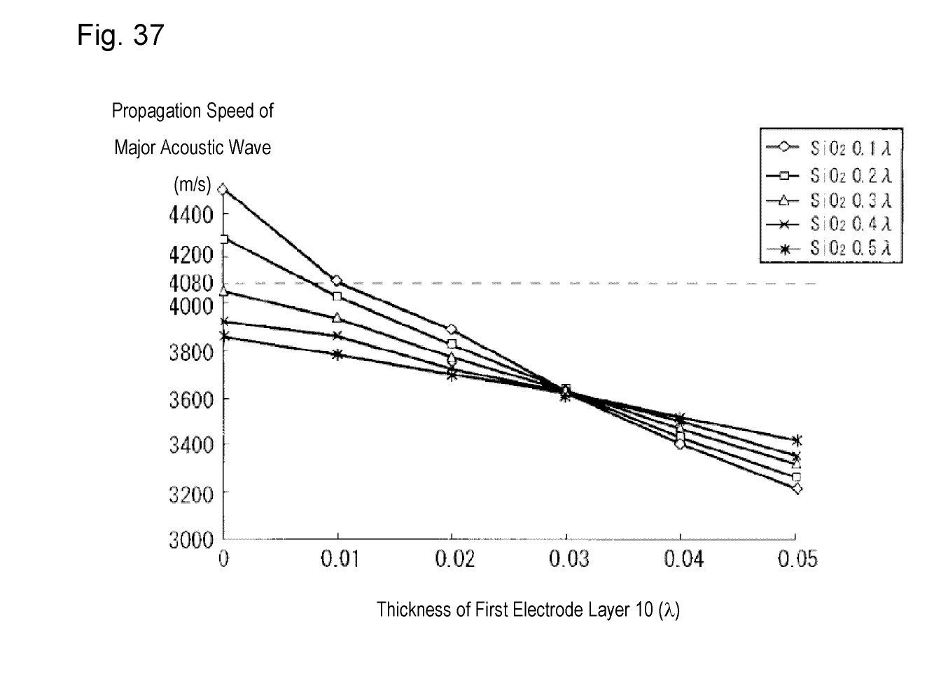

FIG. 37 shows the relation between the thickness (λ) of first electrode layer 10 and the propagation speed (m/s) of the main acoustic waves that propagate through IDT electrodes 7 in the case that the cross section of projections 12 have the same shape as that of the electrode fingers of IDT electrodes 7; piezoelectric body 6 is made of a 25 degree rotated Y-cut X-propagation lithium niobate substrate; and the thickness D of silicon oxide film 8 is changed in the range from 0.1λ to 0.5λ. It is assumed that second electrode layer 11 has a thickness of 0.026λ. As the thickness of second electrode layer 11 becomes larger than this, the propagation speed of the main acoustic waves becomes slightly smaller.

As shown in FIG. 37, in the case that the thickness of silicon oxide film 8 is 0.1λ, if the thickness of first electrode layer 10 is not less than 0.016λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.2λ, if the thickness of first electrode layer 10 is not less than 0.007λ, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

In the case that the thickness of silicon oxide film 8 is 0.3λ, 0.4λ, or 0.5λ, even if first electrode layer 10 is not provided, the propagation speed of the main acoustic waves that propagate through IDT electrodes 7 is lower than the propagation speed (4080 m/s) of the slow transverse wave (bulk wave) that propagates through piezoelectric body 6. This can reduce the energy loss of the main acoustic waves due to bulk wave radiation.

Projections 12 thus provided on the upper surface of silicon oxide film 8 above the electrode fingers of IDT electrodes 7 slightly reduce the propagation speed of the main acoustic waves that propagate through IDT electrodes 7. Thus, even if first electrode layer 10 has a small thickness, the energy loss of the main acoustic waves due to bulk wave radiation is lower than in the device including no projection 12.

Thus, projections 12 on the upper surface of silicon oxide film 8 above the fingers of IDT electrodes 7 can reduce the energy loss of the main acoustic waves due to bulk wave radiation under the following conditions. The propagation speed of the main acoustic waves that propagate through IDT electrodes 7 is lower than the propagation speed (4080 m/s) of the slowest transverse wave (bulk wave) that propagate through piezoelectric body 6, thereby reducing the energy loss of the main acoustic waves due to bulk wave radiation in the following conditions: the thickness of first electrode layer 10 is not less than 0.01λ in the case that the thickness of silicon oxide film 8 is not less than 0.1λ and is less than 0.2λ; and the thickness of first electrode layer 10 is not less than 0.007λ in the case that the thickness of silicon oxide film 8 is not less than 0.3λ and is less than 0.3λ.

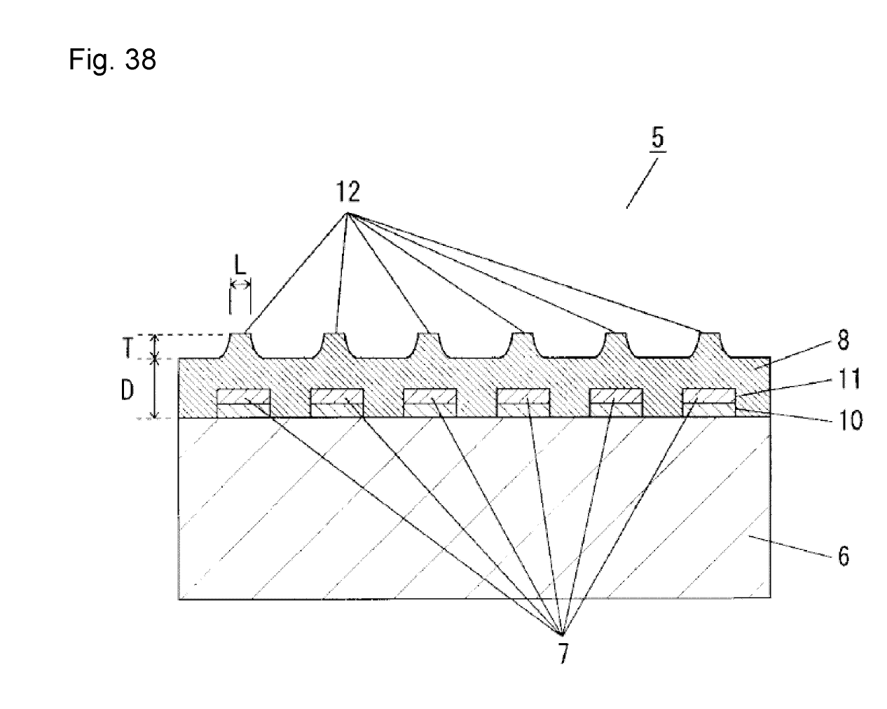

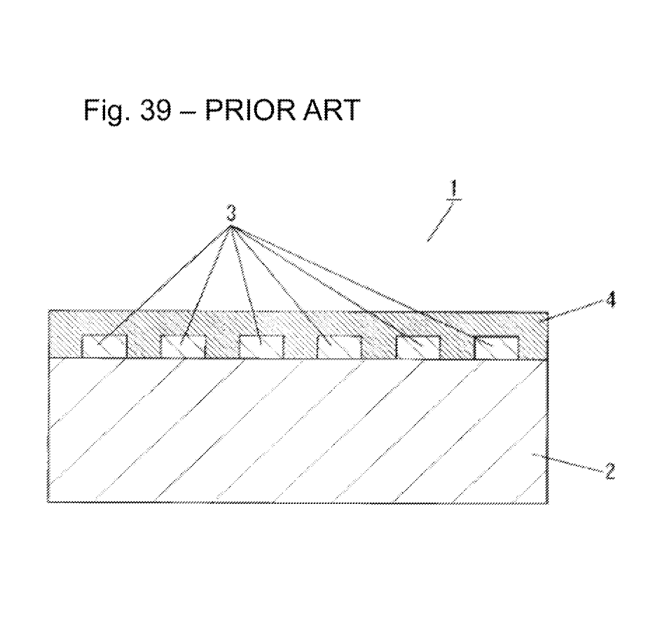

As shown in FIG. 38, in the case that the cross section of projections 12 is smaller than that of the electrode fingers of IDT electrode 7, the propagation speed of the main acoustic waves propagating through first electrode layer 10 has a value between the values shown in FIGS. 35 and 37.

Projections 12 will be detailed below.

Projections 12 of silicon oxide film 8 are preferably curved concavely from the top to the bottom. The width L of the top portion of projection 12 is defined as the distance between two points where either the concave curves or extension lines thereof intersects with a straight line which is parallel to the upper surface of piezoelectric body 6 and which passes the top of the projection. In this case, the width L of the top portion is smaller than the width of the fingers of IDT electrodes 7. This structure allows a mass added to silicon oxide film 8 at projections 12 to change continuously and gradually and prevents unwanted reflections due to the shape of silicon oxide film 8, thereby improving the electrical characteristics of acoustic wave device 5.

The width of the top portions of projections 12 is preferably one half or less of the width of the fingers of IDT electrode 7. The center positions of the top portions of projections 12 are preferably substantially directly above the center positions of the electrode fingers. This further improves the reflectance at the electrode fingers due to the mass addition effect, thereby improving the electrical characteristics of acoustic wave device 5.

The height T of projections 12 and the total thickness h of IDT electrode 7 may preferably satisfy 0.03λ<T≦h. According to a study of the relation between the height T from the bottom portion to the top portion of projections 12 of silicon oxide film 8 and the electrical characteristics, the reflectance is very high in the case that the height T is higher than 0.03λ, and silicon oxide film 8 has a flat surface. If the height T is larger than the thickness h of IDT electrodes 7, an additional process is required to produce silicon oxide film 8, thereby complicating the production method. The method of producing acoustic wave device 5 according to Embodiment 6 is identical to that of Embodiment 2.

It is understood that adhesive layers 15 and 16 of Embodiment 5 can be applied to the IDT electrodes of Embodiment 6.

Acoustic wave device 5 according to Embodiments 1 to 6 may be applied to a filter (not shown), such as a ladder type filter or a DMS filter. This filter may be applied to an antenna duplexer (not shown) including a transmitting filter and a receiving filter. Acoustic wave device 5 may be applied to an electronic device including this filter, a semiconductor IC element (not shown) connected to the filter; and a reproducing unit of, for example, a loudspeaker connected to the semiconductor IC element (not shown).

### INDUSTRIAL APPLICABILITY

An acoustic wave device according to the present invention is capable of reducing insertion loss, and is applicable to electronic devices, such as mobile phones.

### REFERENCE MARKS IN THE DRAWINGS

5 Acoustic Wave Device
6 Piezoelectric Body
7 IDT Electrode
8 Silicon Oxide Film
9 Dielectric Film
10 First Electrode Layer
11 Second Electrode Layer

1. An acoustic wave device comprising:
a piezoelectric body;
an IDT electrode disposed above the piezoelectric body, the IDT electrode exciting a main acoustic wave having a wavelength λ;
a silicon oxide film disposed above the piezoelectric body to cover the IDT electrode, the silicon oxide film having a thickness which is not less than 0.2λ and is less than 1λ; and
a dielectric film disposed above the silicon oxide film, the dielectric film having a thickness ranging from 1λ to 5λ, the dielectric film being made of a medium which allows a transverse wave to propagate through the medium faster than a transverse wave propagating through the silicon oxide film,
wherein the IDT electrode includes:
a first electrode layer disposed above the piezoelectric body, the first electrode layer being mainly made of Mo; and
a second electrode layer disposed above the first electrode layer, the second electrode layer being mainly made of Al,
wherein the IDT electrode has a total thickness not more than 0.15λ;
wherein the first electrode layer has a thickness not less than 0.05λ; and
wherein the second electrode layer has a thickness not less than 0.025λ.

2. The acoustic wave device according to claim 1,
wherein, in a case that the thickness of the silicon oxide film is not less than 0.2λ and is less than 0.3λ, the thickness of the first electrode layer is not less than 0.093λ;
wherein, in a case that the thickness of the silicon oxide film is not less than 0.3λ and is less than 0.5λ, the thickness of the first electrode layer is not less than 0.068λ; and
wherein, in a case that the thickness of the silicon oxide film is not less than 0.5λ and is less than 1λ, the thickness of the first electrode layer is not less than 0.05λ.

3. An acoustic wave device comprising:
a piezoelectric body;
an IDT electrode disposed above the piezoelectric body, the IDT electrode exciting a main acoustic wave having a wavelength λ; and
a silicon oxide film disposed above the piezoelectric body to cover the IDT electrode, the silicon oxide film having a thickness which is not less than 0.2λ and is less than 0.5λ,
wherein the IDT electrode includes:
a first electrode layer disposed above the piezoelectric body, the first electrode layer being mainly made of Mo; and
a second electrode layer disposed above the first electrode layer, the second electrode layer being mainly made of Al,
wherein the IDT electrode has a total thickness not more than 0.15λ;
wherein the first electrode layer has a thickness not less than 0.03λ; and
wherein the second electrode layer has a thickness not less than 0.025λ.

4. The acoustic wave device according to claim 3,
wherein, in a case that the thickness of the silicon oxide film is not less than 0.2λ and is less than 0.3λ, the thickness of the first electrode layer is not less than 0.038λ; and
wherein, in a case that the thickness of the silicon oxide film is not less than 0.3λ and is less than 0.5λ, the thickness of the first electrode layer is not less than 0.03λ.

5. The acoustic wave device according to claim 3,
wherein, in a case that the piezoelectric body has an Euler angle (φ, θ, ψ) where −10°≦φ≦10°, 33°≦θ≦43°, −10°≦ψ≦10°, and
wherein a thickness H of the silicon oxide film 8, a thickness h of the first electrode layer, and a ratio η of a width of an electrode finger of the IDT electrode to a pitch of the IDT electrode satisfy following relations:
in a case that H/h is not less than 5.00 and is less than 6.25, h/λ is not less than 4.5% if η is not less than 0.3 and is less than 0.4 or if η is not less than 0.6 and is less than 0.7;
in a case that H/h is not less than 5.00 and is less than 6.25, h/λ is not less than 3.5% if η is not less than 0.4 and is less than 0.6; and
in a case that H/h ranges from 6.25 to 8.75, h/λ is not less than 3.5%.

6. An acoustic wave device comprising:
a piezoelectric body;
an IDT disposed above the piezoelectric body, the IDT electrode exciting a main acoustic wave having a wavelength λ;
a silicon oxide film disposed above the piezoelectric body to cover the IDT electrode, the silicon oxide film having a thickness ranging from 0.2λ to 0.5λ; and
a dielectric film disposed above the silicon oxide film, the dielectric film having a thickness ranging from 1λ to 5λ and made of a medium which allows a transverse wave to propagate through the dielectric film faster than a transverse wave propagating through the silicon oxide film,
wherein the IDT electrode includes:
a first electrode layer disposed above the piezoelectric body, the first electrode layer being mainly made of W (tungsten); and
a second electrode layer disposed above the first electrode layer, the second electrode layer being mainly made of Al (aluminum),
wherein the IDT electrode has a total thickness not more than 0.15λ;
wherein the first electrode layer has a thickness not less than 0.03λ; and
wherein the second electrode layer has a thickness not less than 0.026λ.

7. The acoustic wave device according to claim 6,
wherein, in a case that the thickness of the silicon oxide film is not less than 0.2λ and is less than 0.3λ, the thickness of the first electrode layer is not less than 0.04λ,
wherein, in a case that the thickness of the silicon oxide film is not less than 0.3λ and is less than 0.4λ, the thickness of the first electrode layer is not less than 0.037λ; and
wherein, in a case that the thickness of the silicon oxide film ranges from 0.4λ to 0.5λ, the thickness of the first electrode layer is not less than 0.03λ.

8. An acoustic wave device comprising:
a piezoelectric body;
an IDT electrode disposed above the piezoelectric body, the IDT electrode exciting a main acoustic wave having a wavelength λ; and
a silicon oxide film disposed above the piezoelectric body to cover the IDT electrode, the silicon oxide film having a thickness ranging from 0.2λ to 0.5λ,
wherein the IDT electrode includes:
a first electrode layer disposed above the piezoelectric body, the first electrode layer being mainly made of W (tungsten); and
a second electrode layer disposed above the first electrode layer, the second electrode layer being mainly made of Al (aluminum),
wherein the IDT electrode has a total thickness not more than 0.15λ;
wherein the first electrode layer has a thickness not less than 0.004λ; and
wherein the second electrode layer has a thickness not less than 0.026λ.

9. The acoustic wave device according to claim 8,
wherein, in a case that the thickness of the silicon oxide film is not less than 0.1λ and is less than 0.2λ, the thickness of the first electrode layer is not less than 0.027λ,
wherein, in a case that the thickness of the silicon oxide film is not less than 0.2λ and is less than 0.3λ, the thickness of the first electrode layer is not less than 0.02λ,
wherein, in a case that the thickness of the silicon oxide film is not less than 0.3λ and is less than 0.4λ, the thickness of the first electrode layer is not less than 0.018λ,
wherein, in a case that the thickness of the silicon oxide film is not less than 0.4λ and is less than 0.5λ, the thickness of the first electrode layer is not less than 0.01λ, and
wherein, in a case that the thickness of the silicon oxide film is 0.5λ, the thickness of the first electrode layer is not less than 0.004λ.

10. An acoustic wave device comprising:
a piezoelectric body;
an IDT electrode disposed above the piezoelectric body, the IDT electrode exciting a main acoustic wave having a wavelength λ;
a silicon oxide film disposed above the piezoelectric body to cover the IDT electrode, the silicon oxide film having a thickness ranging from 0.2λ to 0.5λ; and
a dielectric film disposed above the silicon oxide film, the dielectric film having a thickness ranging from 1λ to 5λ and made of a medium which allows a transverse wave to propagate through the dielectric film faster than a transverse wave propagating through the silicon oxide film,
wherein the IDT electrode includes:
a first electrode layer disposed above the piezoelectric body, the first electrode layer being mainly made of Pt (platinum); and
a second electrode layer disposed above the first electrode layer, the second electrode layer being mainly made of Al (aluminum),
wherein the IDT electrode has a total thickness not more than 0.15λ;
wherein the first electrode layer has a thickness not less than 0.025λ; and
wherein the second electrode layer has a thickness not less than 0.026λ.

11. The acoustic wave device according to claim 10,
wherein, in a case that the thickness of the silicon oxide film is not less than 0.2λ and is less than 0.3λ, the thickness of the first electrode layer is not less than 0.035λ,
wherein, in a case that the thickness of the silicon oxide film is not less than 0.3λ and is less than 0.4λ, the thickness of the first electrode layer is not less than 0.029λ,
wherein, in a case that the thickness of the silicon oxide film is not less than 0.4λ and is less than 0.5λ, the thickness of the first electrode layer is not less than 0.027λ, and
wherein, in a case that the thickness of the silicon oxide film is 0.5λ, the thickness of the first electrode layer is not less than 0.025λ.

12. An acoustic wave device comprising:
a piezoelectric body;
an IDT electrode disposed above the piezoelectric body, the IDT electrode exciting a main acoustic wave of a wavelength λ; and
a silicon oxide film disposed above the piezoelectric body to cover the IDT electrode, the silicon oxide film having a thickness which is not less than of 0.2λ and is less than 0.5λ,
wherein the IDT electrode includes:
a first electrode layer disposed above the piezoelectric body, the first electrode layer being mainly made of Pt (platinum); and
a second electrode layer disposed above the first electrode layer, the second electrode layer being mainly made of Al (aluminum),
wherein the IDT electrode has a total thickness not more than 0.15λ,
wherein the first electrode layer has a thickness not less than 0.009λ, and
wherein the second electrode layer has a thickness not less than 0.026λ.

13. The acoustic wave device according to claim 12,
wherein, in a case that the thickness of the silicon oxide film is not less than 0.1λ and is less than 0.2λ, the thickness of the first electrode layer is not less than 0.02λ,
wherein, in a case that the thickness of the silicon oxide film is not less than 0.2λ and is less than 0.3λ, the thickness of the first electrode layer is not less than 0.018λ,
wherein, in a case that the thickness of the silicon oxide film is not less than 0.3λ and is less than 0.4λ, the thickness of the first electrode layer is not less than 0.016λ, and
wherein, the thickness of the silicon oxide film is not less than 0.4λ and is less than 0.5λ, the thickness of the first electrode layer is not less than 0.009λ.

14. The acoustic wave device according to claim 3, wherein the silicon oxide film has a projection on an upper surface thereof, the projection being located above an electrode finger of the IDT electrode.

15. The acoustic wave device according to claim 14, wherein a top portion of the projection has a width smaller than a width of the electrode finger of the IDT electrode.

16. The acoustic wave device according to claim 3, wherein the second electrode layer extends onto a part of a side surface of the first electrode layer.

17. The acoustic wave device according to claim 8, wherein the silicon oxide film has a projection on an upper surface thereof, the projection being located above an electrode finger of the IDT electrode.

18. The acoustic wave device according to claim 12, wherein the silicon oxide film has a projection on an upper surface thereof, the projection being located above an electrode finger of the IDT electrode.

19. The acoustic wave device according to claim 8, wherein the second electrode layer extends onto a part of a side surface of the first electrode layer.

20. The acoustic wave device according to claim 14, wherein the second electrode layer extends onto a part of a side surface of the first electrode layer.
